(19) United States
(12) Patent Application Publication
(10) Pub. No.: US 2026/0213708 A1
(43) Pub. Date: Jul. 23, 2026

(54) CIRCUIT DEVICE AND OSCILLATOR

(71) Applicant: SEIKO EPSON CORPORATION, Tokyo (JP)

(72) Inventor: Wataru Okumura, Minamiminowa-mura (JP)

(21) Appl. No.: 19/453,122

(22) Filed: Jan. 20, 2026

(30) Foreign Application Priority Data
Jan. 21, 2025 (JP) 2025-008210

(51) Int. Cl. H03B 5/04; H03B 5/36

(52) U.S. Cl. CPC H03B 5/04; H03B 5/36

(57) ABSTRACT

A circuit device includes an oscillation circuit configured to cause a resonator to oscillate and generate an oscillation signal, a temperature compensation circuit configured to output a temperature compensation voltage for an oscillation frequency of the oscillation signal to the oscillation circuit based on a temperature detection voltage from a temperature detection circuit, a power supply circuit configured to generate a power supply voltage of the temperature compensation circuit, and a reference voltage generation circuit for temperature compensation configured to generate a reference voltage for temperature compensation and output the reference voltage to the temperature compensation circuit. Noise of the reference voltage is smaller than noise of the power supply voltage, and a temperature characteristic of the power supply voltage is flatter than a temperature characteristic of the reference voltage.

The present application is based on, and claims priority from JP Application Serial Number 2025-008210, filed Jan. 21, 2025, the disclosure of which is hereby incorporated by reference herein in its entirety.

### BACKGROUND

### 1. Technical Field

The present disclosure relates to a circuit device and an oscillator.

### 2. Related Art

In a circuit device that causes a resonator such as a quartz crystal resonator to oscillate, temperature compensation of an oscillation frequency is performed. For example, JP-A-2023-90099 discloses a circuit device that performs such a temperature compensation. In the circuit device in the related art, as a voltage generation circuit capable of generating a voltage having a flat temperature characteristic with low noise, a circuit in which a bandgap reference circuit and a regulator are combined is used.

However, when the power supply voltage supplied from the outside is lowered, it is found that the voltage generation circuit having the above configuration has a problem that it is difficult to achieve both low noise and a flat temperature characteristic.

### SUMMARY

According to an aspect of the present disclosure, there is provided a circuit device including an oscillation circuit configured to cause a resonator to oscillate and generate an oscillation signal, a temperature compensation circuit configured to output a temperature compensation voltage for an oscillation frequency of the oscillation signal to the oscillation circuit based on a temperature detection voltage from a temperature detection circuit, a power supply circuit configured to generate a power supply voltage of the temperature compensation circuit, and a reference voltage generation circuit for temperature compensation configured to generate a reference voltage for temperature compensation and output the reference voltage to the temperature compensation circuit, in which noise of the reference voltage is smaller than noise of the power supply voltage, and a temperature characteristic of the power supply voltage is flatter than a temperature characteristic of the reference voltage.

According to another aspect of the present disclosure, there is provided an oscillator including the circuit device according to the above aspect, and the resonator.

### BRIEF DESCRIPTION OF THE DRAWINGS

FIG. 1 is a configuration example of a circuit device according to the present embodiment.

FIG. 2 is a detailed configuration example of the circuit device and an oscillator according to the present embodiment.

FIG. 3 is a configuration example of a temperature compensation circuit.

FIG. 4 is an explanatory diagram regarding voltage supply of a reference voltage generation circuit and a power supply circuit.

FIG. 5 is a configuration example of a voltage generation circuit of the reference voltage generation circuit.

FIG. 6 is a configuration example of a reference circuit of the reference voltage generation circuit.

FIG. 7 is a configuration example of an inverting amplifier circuit.

FIG. 8 is a configuration example of an operational amplifier.

FIG. 9 is a configuration example of the reference voltage generation circuit for generating a low-noise reference voltage.

FIG. 10 is a configuration example of a power supply circuit for generating a power supply voltage having a flat temperature characteristic.

FIG. 11 is a configuration example of the reference voltage generation circuit and the power supply circuit.

FIG. 12 is a diagram showing an example of a noise characteristic of a regulated voltage.

FIG. 13 is a diagram showing an example of a temperature characteristic of a power supply voltage.

FIG. 14 is a configuration example of the reference circuit of the power supply circuit.

FIG. 15 is a configuration example of the reference circuit of the power supply circuit.

FIG. 16 is a configuration example of a regulator.

FIG. 17 is a configuration example of a PTAT current source.

FIG. 18 is a configuration example of a CTAT current source.

### DESCRIPTION OF EMBODIMENTS

In the following, the present embodiment will be described. The present embodiment to be described below does not unreasonably limit the contents described in the claims. In addition, not all configurations described in the present embodiment are essential configuration requirements.

### 1. Circuit Device

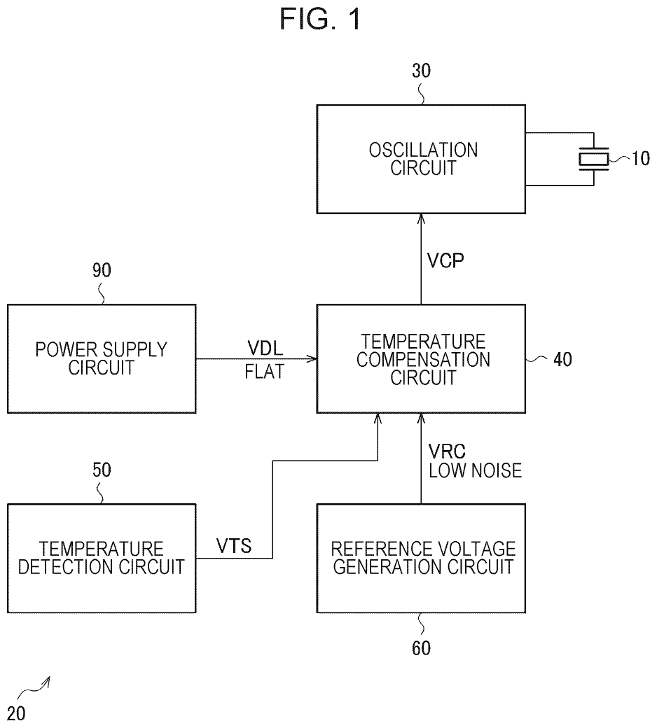

FIG. 1 shows a configuration example of a circuit device 20 according to the present embodiment. The circuit device 20 of the present embodiment includes an oscillation circuit 30, a temperature compensation circuit 40, a reference voltage generation circuit 60, and a power supply circuit 90. In addition, the circuit device 20 may include a temperature detection circuit 50. In addition, the resonator 10 is electrically coupled to the circuit device 20, and for example, an oscillator is configured by the resonator 10 and the circuit device 20. The configuration of the circuit device 20 is not limited to the configuration of FIG. 1, and various modifications such as omitting some of the components, adding other components, and replacing some of the components with other components can be implemented.

The resonator 10 is an element that generates mechanical resonance by an electrical signal. The resonator 10 can be realized by a resonator element such as a quartz crystal resonator element. For example, the resonator 10 can be realized by a quartz crystal resonator element having a cut angle that thickness-shear resonates, such as an AT cut or an SC cut, a tuning fork type quartz crystal resonator element, a double tuning fork type quartz crystal resonator element, or the like. For example, the resonator 10 may be a resonator built in a temperature compensated crystal oscillator (TCXO) that does not include a constant temperature bath, or may be a resonator built in an oven controlled crystal oscillator (OCXO) that includes a constant temperature bath. The resonator 10 of the present embodiment can also be realized by various resonator elements such as a resonator element other than a thickness-shear resonance type, a tuning fork type, a double tuning fork type, or a piezoelectric resonator element formed of a material other than quartz crystal. For example, as the resonator 10, a surface acoustic wave (SAW) resonator, a micro electro mechanical systems (MEMS) resonator as a silicon resonator formed by using a silicon substrate, or the like can be adopted.

The circuit device 20 is an integrated circuit device called an integrated circuit (IC). For example, the circuit device 20 is an IC manufactured by a semiconductor process, and is a semiconductor chip in which circuitry is formed on a semiconductor substrate. The circuit device 20 operates based on a power supply voltage supplied from the outside.

The oscillation circuit 30 is a circuit that causes the resonator 10 to oscillate. For example, the oscillation circuit 30 generates an oscillation signal by oscillating the resonator 10. For example, the oscillation signal is an oscillation clock signal. For example, the oscillation circuit 30 can be realized by a drive circuit for oscillation that is electrically coupled to one end and the other end of the resonator 10, and a passive element such as a capacitor and a resistor. For example, the drive circuit can be realized by a CMOS inverter circuit or a bipolar transistor. The drive circuit is a core circuit of the oscillation circuit 30, and the drive circuit causes the resonator 10 to oscillate by voltage-driving or current-driving the resonator 10. As the oscillation circuit 30, various types of oscillation circuits such as an inverter type, a Pierce type, a Colpitts type, and a Hartley type can be used. It should be noted that coupling in the present embodiment is electrical coupling. The electrical coupling is coupling in which electrical signals are coupled so as to be transmittable, and is coupling that enables transmission of information by electrical signals. The electrical coupling may be coupling via the passive element or the like.

The temperature detection circuit 50 is a sensor circuit that detects a temperature. Specifically, the temperature detection circuit 50 outputs a temperature-dependent voltage that changes according to the ambient temperature as a temperature detection voltage VTS. For example, the temperature detection circuit 50 generates a temperature detection voltage VTS, which is a temperature detection signal, by using a circuit element having temperature dependency. Specifically, the temperature detection circuit 50 outputs a temperature detection voltage VTS whose voltage changes depending on the temperature by using, for example, temperature dependency of a forward voltage of a PN junction. A modification in which a digital type temperature detection circuit is used as the temperature detection circuit 50 is also possible. In this case, the temperature detection voltage VTS may be generated by performing D/A conversion on temperature detection data.

The temperature compensation circuit 40 performs temperature compensation of the oscillation frequency of the oscillation circuit 30. For example, the temperature compensation circuit 40 outputs a temperature compensation voltage VCP of the oscillation frequency of the oscillation signal to the oscillation circuit 30 based on the temperature detection voltage VTS from the temperature detection circuit 50. The temperature compensation is processing of suppressing and compensating for fluctuations of the oscillation frequency due to the temperature fluctuations, for example. That is, the temperature compensation circuit 40 performs the temperature compensation of the oscillation frequency of the oscillation circuit 30 such that the oscillation frequency is constant even when the temperature fluctuates. It is also possible to perform a modification in which the oscillation frequency is digitally adjusted in a variable capacitance circuit of the oscillation circuit 30 by using temperature compensation data obtained by A/D converting the temperature compensation voltage VCP.

The power supply circuit 90 is supplied with, for example, a power supply voltage or a ground voltage from the outside, and supplies various power supply voltages for internal circuits of the circuit device 20 to the internal circuits. For example, the power supply circuit 90 supplies a power supply voltage obtained by regulating a power supply voltage, or the like, to each circuit of the circuit device 20, such as the oscillation circuit 30, the temperature compensation circuit 40, and the temperature detection circuit 50. In FIG. 1, the power supply circuit 90 generates a power supply voltage VDL of the temperature compensation circuit 40 and outputs the power supply voltage VDL to the temperature compensation circuit 40. For example, the operational amplifier included in the temperature compensation circuit 40 operates using the power supply voltage VDL as a power supply. For example, the operational amplifier is an amplifier used in a current-voltage conversion circuit of the temperature compensation circuit 40 or a correction circuit for temperature compensation.

The reference voltage generation circuit 60 for temperature compensation generates a reference voltage VRC for temperature compensation. The generated reference voltage VRC is output to the temperature compensation circuit 40. The temperature compensation circuit 40 generates a temperature compensation voltage VCP by performing the temperature compensation based on the reference voltage VRC. For example, the temperature compensation voltage VCP is set to be the reference voltage VRC at a temperature of an inflection point of temperature compensation. The temperature compensation voltage VCP changes with reference to the reference voltage VRC, for example, changes to a positive side with respect to the reference voltage VRC or changes to a negative side with respect to the reference voltage VRC. The temperature of the inflection point is, for example, a typical temperature, and is, for example, −25° C. For example, a higher-order temperature compensation current generated by the temperature compensation circuit 40 is set to be, for example, 0 at the temperature of the inflection point.

In the present embodiment, noise of the reference voltage VRC generated by the reference voltage generation circuit 60 is smaller than noise of the power supply voltage VDL generated by the power supply circuit 90. That is, the reference voltage generation circuit 60 generates a reference voltage VRC having lower noise than the power supply voltage VDL from the power supply circuit 90 and outputs the reference voltage VRC to the temperature compensation circuit 40. Here, the noise is, for example, voltage noise, and is noise power represented by, for example, a root mean square (RMS) value.

On the other hand, a temperature characteristic of the power supply voltage VDL generated by the power supply circuit 90 is flatter than the temperature characteristic of the reference voltage VRC. For example, the voltage fluctuation of the power supply voltage VDL in a usage temperature range defined by the specifications of the circuit device 20 or the oscillator is smaller than the voltage fluctuation of the reference voltage VRC in the usage temperature range, and the temperature characteristics are flat. In other words, a slope of a first-order temperature characteristic of the power supply voltage VDL is smaller than a slope of a first-order temperature characteristic of the reference voltage VRC. Here, the usage temperature range is, for example, −40° C. to 105° C., but is not limited thereto, and may be, for example, −40° C. to 125° C. or 0° C. to 85° C.

In this manner, in the present embodiment, although the temperature characteristic is not flat as compared with the power supply voltage VDL, a voltage having lower noise than the power supply voltage VDL is used as the reference voltage VRC for temperature compensation in the temperature compensation circuit 40. On the other hand, a voltage having larger noise than the reference voltage VRC but having a flatter temperature characteristic than the reference voltage VRC is used as a power supply voltage VDL of the temperature compensation circuit 40. In this way, it is possible to realize temperature compensation without impairing the characteristics even when the power supply voltage supplied from the outside becomes low.

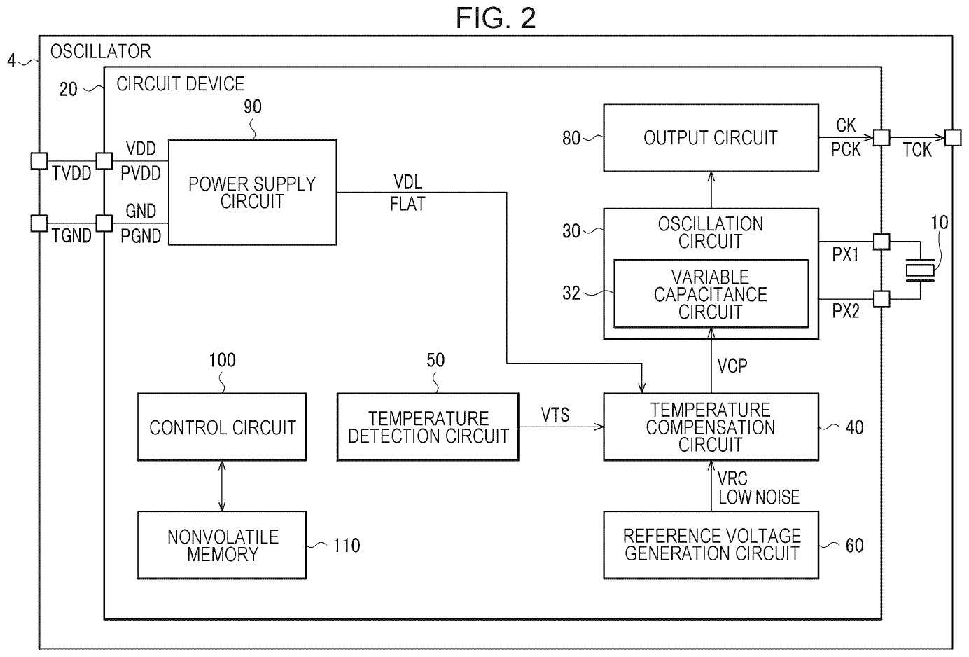

FIG. 2 shows a detailed configuration example of the circuit device 20 and an oscillator 4 according to the present embodiment. In FIG. 2, the circuit device 20 includes the temperature detection circuit 50, an output circuit 80, a control circuit 100, and a nonvolatile memory 110 in addition to the oscillation circuit 30, the temperature compensation circuit 40, the reference voltage generation circuit 60, and the power supply circuit 90. In addition, the oscillator 4 includes the resonator 10 and the circuit device 20, and the resonator 10 is electrically coupled to the circuit device 20. For example, the resonator 10 and the circuit device 20 are electrically coupled to each other by using internal wiring of a package that accommodates the resonator 10 and the circuit device 20, a bonding wire, a metal bump, or the like. The configurations of the circuit device 20 and the oscillator 4 are not limited to the configuration of FIG. 2, and various modifications can be made such as omitting some of the components, adding other components, and replacing some of the components with other components.

The circuit device 20 further includes pads PVDD, PGND, PX1, PX2, and PCK. The pads are terminals of the circuit device 20, which is a semiconductor chip. For example, in a pad region, a metal layer is exposed from a passivation film, which is an insulating layer, and the pad, which is the terminal of the circuit device 20, is configured by the exposed metal layer. The pads PVDD and PGND are a power supply pad and a ground pad, respectively. The power supply voltage VDD from an external power supply device is supplied to the pad PVDD. The pad PGND is a pad to which GND, which is the ground voltage, is supplied. For example, the ground voltage is a ground potential. In the present embodiment, GND is referred to as VSS as appropriate. For example, VDD corresponds to a high potential side power supply, and VSS, which is GND, corresponds to a low potential side power supply. The pads PX1 and PX2 are pads for coupling of the resonator 10. The pad PCK is a pad for outputting a clock signal CK. The pads PVDD, PGND, and PCK are electrically coupled to terminals TVDD, TGND, and TCK, which are external terminals for external coupling of the oscillator 4, respectively. For example, each of these pads and each of the terminals are electrically coupled by using internal wiring of the package, bonding wires, metal bumps, or the like. A terminal and a pad to which a control voltage from the outside is input may be provided so that an external system can control an oscillation frequency by the control voltage.

The oscillation circuit 30 is electrically coupled to the resonator 10 via the pads PX1 and PX2. The pads PX1 and PX2 are pads for coupling of the resonator. The drive circuit for oscillation of the oscillation circuit 30 is provided between the pad PX1 and the pad PX2. The oscillation circuit 30 includes a variable capacitance circuit 32. For example, the variable capacitance circuit 32 is a circuit that changes capacitance of at least one of the one end and the other end of the resonator 10, and the oscillation frequency of the oscillation circuit 30 can be adjusted by adjusting the capacitance of the variable capacitance circuit 32. That is, the variable capacitance circuit 32 is electrically coupled to at least one of the pads PX1 and PX2, so that load capacitance of the oscillation circuit 30 can be variably adjusted. The variable capacitance circuit 32 can be realized by, for example, a variable capacitance element such as a varactor. For example, the variable capacitance circuit 32 is configured by at least one variable capacitance element.

The temperature compensation circuit 40 performs analog temperature compensation by using, for example, polynomial approximation. For example, when the temperature compensation voltage VCP for compensating a frequency-temperature characteristic of the resonator 10 is approximated by a polynomial, the temperature compensation circuit 40 performs analog temperature compensation based on coefficient information of the polynomial. The analog temperature compensation is temperature compensation that is realized by, for example, addition processing of a current signal or a voltage signal, which is an analog signal. For example, when the temperature compensation voltage VCP is approximated by a higher-order polynomial, the zeroth-order coefficient, the first-order coefficient, and the higher-order coefficient of the polynomial are stored in a storage portion realized by, for example, the nonvolatile memory 110 or the like as zeroth-order correction data, first-order correction data, and higher-order correction data, respectively. The higher-order coefficient is, for example, a coefficient of a higher order than the first order, and the higher-order correction data is correction data corresponding to the higher-order coefficient. For example, when the temperature compensation voltage VCP is approximated by a third-order polynomial, a zeroth-order coefficient, a first-order coefficient, a second-order coefficient, and a third-order coefficient of the polynomial are stored in the storage portion as zeroth-order correction data, first-order correction data, second-order correction data, and third-order correction data. The temperature compensation circuit 40 performs temperature compensation based on the zeroth-order correction data to the third-order correction data. In this case, the second-order correction data and temperature compensation based on the second-order correction data may be omitted. In addition, for example, when the temperature compensation voltage VCP is approximated by a fifth-order polynomial, a zeroth-order coefficient, a first-order coefficient, a second-order coefficient, a third-order coefficient, a fourth-order coefficient, and a fifth-order coefficient of the polynomial are stored in the storage portion as zeroth-order correction data, first-order correction data, second-order correction data, third-order correction data, fourth-order correction data, and fifth-order correction data. The temperature compensation circuit 40 performs the temperature compensation based on the zeroth-order correction data to the fifth-order correction data. In this case, the second-order correction data or the fourth-order correction data, or the temperature compensation based on the second-order correction data or the fourth-order correction data may be omitted. The order of polynomial approximation may be optional, and, for example, polynomial approximation of an order higher than fifth order may be performed.

The control circuit 100 is a circuit that performs various control processing, and is realized by, for example, a logic circuit or the like. For example, the control circuit 100 performs the overall control of the circuit device 20 or performs control of an operation sequence of the circuit device 20. The control circuit 100 performs various processing for controlling the oscillation circuit 30, performs control of the temperature compensation circuit 40, the temperature detection circuit 50, the reference voltage generation circuit 60, the output circuit 80, or the power supply circuit 90, or performs control of reading or writing of information of the nonvolatile memory 110. The control circuit 100 can be realized by, for example, a circuit of an application specific integrated circuit (ASIC) by automatic arrangement wiring such as a gate array.

The nonvolatile memory 110 is a memory that holds stored information even when power is not supplied. For example, the nonvolatile memory 110 is a memory that can hold information even when power is not supplied and can rewrite the information. The nonvolatile memory 110 stores various information necessary for the operation of the circuit device 20. The nonvolatile memory 110 can be realized by an electrically erasable programmable read-only memory (EEPROM) realized by a floating gate avalanche injection MOS memory (FAMOS memory) or a metal-oxide-nitride-oxide-silicon memory (MONOS memory), or the like. The nonvolatile memory 110 stores correction data such as first-order correction data and higher-order correction data used for temperature compensation of the temperature compensation circuit 40.

The output circuit 80 outputs a clock signal CK based on the oscillation signal of the oscillation circuit 30. For example, the output circuit 80 buffers the oscillation signal, which is an oscillation clock signal from the oscillation circuit 30 and outputs the oscillation signal to the pad PCK as the clock signal CK. The clock signal CK is output to the outside via a clock output terminal TCK of the oscillator 4. For example, the output circuit 80 outputs a clock signal CK in a single-ended CMOS signal format. The output circuit 80 may output a clock signal CK in a signal format other than CMOS. In addition, a clock signal generation circuit such as a PLL circuit that generates a clock signal CK having a frequency obtained by multiplying the frequency of the oscillation signal may be provided in the subsequent stage of the oscillation circuit 30, and the output circuit 80 may buffer and output the clock signal CK generated by the clock signal generation circuit.

The reference voltage generation circuit 60 for temperature compensation generates a low-noise reference voltage VRC for temperature compensation and outputs the reference voltage VRC to the temperature compensation circuit 40. For example, the reference voltage generation circuit 60 includes a reference circuit for generating a BGR voltage. BGR is an abbreviation for bandgap reference. The reference voltage generation circuit 60 generates a reference voltage VRC based on the BGR voltage generated by the reference circuit. In this case, the reference voltage generation circuit 60 may have a regulator and generate a reference voltage VRC based on a voltage generated by the regulator based on the BGR voltage. For example, the regulator regulates the power supply voltage VDD based on the BGR voltage, and the reference voltage generation circuit 60 generates a reference voltage VRC based on the voltage generated by the regulator. For example, the reference voltage generation circuit 60 generates a reference voltage VRC by using, as a reference power supply voltage, the BGR voltage generated by the reference circuit or the voltage generated by the regulator based on the BGR voltage. For example, the reference voltage generation circuit 60 generates a reference voltage VRC by voltage-dividing the reference power supply voltage by a voltage generation circuit configured by a resistor circuit or the like. In this case, as will be described later, a plurality of reference voltages may be generated by changing a resistance division ratio in the voltage generation circuit and may be supplied to the temperature compensation circuit 40.

The power supply circuit 90 is supplied with the power supply voltage VDD from the pad PVDD and VSS, which is the ground voltage GND from the pad PGND, and supplies various power supply voltages for the internal circuits of the circuit device 20 to the internal circuits. For example, the power supply circuit 90 supplies a voltage obtained by regulating the power supply voltage VDD to each circuit of the circuit device 20 such as the oscillation circuit 30.

In the present embodiment, the power supply circuit 90 generates a power supply voltage VDL having a flat temperature characteristic and supplies the power supply voltage VDL to the temperature compensation circuit 40. For example, the power supply circuit 90 includes a reference circuit that generates a reference voltage for power supply, and generates a power supply voltage VDL based on the reference voltage for power supply. In addition, the power supply circuit 90 may include a regulator, and the regulator may generate a power supply voltage VDL based on the reference voltage for power supply. For example, the regulator regulates the power supply voltage VDD based on the reference voltage for power supply to generate a power supply voltage VDL. The operational amplifier or the like included in the temperature compensation circuit 40 operates with the power supply voltage VDD as a power supply.

The oscillation circuit 30 includes a variable capacitance circuit 32 having, for example, a positive characteristic of capacitance change with respect to a capacitance control voltage. The positive characteristic of capacitance change means a change characteristic in which capacitance increases as the capacitance control voltage increases. The change characteristic of the capacitance of the variable capacitance circuit 32 may be a negative characteristic. The temperature compensation circuit 40 supplies the temperature compensation voltage VCP, as the capacitance control voltage, to the variable capacitance circuit 32. Since the variable capacitance circuit 32 is a variable capacitance circuit having a positive characteristic, when the temperature compensation voltage VCP from the temperature compensation circuit 40 increases, capacitance of the variable capacitance circuit 32 increases, and an oscillation frequency of the oscillation circuit 30 decreases. Accordingly, it is possible to realize the temperature compensation for offsetting the increase in the oscillation frequency. Further, when the temperature compensation voltage VCP from the temperature compensation circuit 40 decreases, the capacitance of the variable capacitance circuit 32 decreases, and the oscillation frequency of the oscillation circuit 30 increases. Accordingly, it is possible to realize the temperature compensation for offsetting the decrease in the oscillation frequency. A variable capacitance circuit whose capacitance is controlled by a frequency control voltage input from the outside may be provided in the oscillation circuit 30, and an oscillation frequency may be variable by the frequency control voltage.

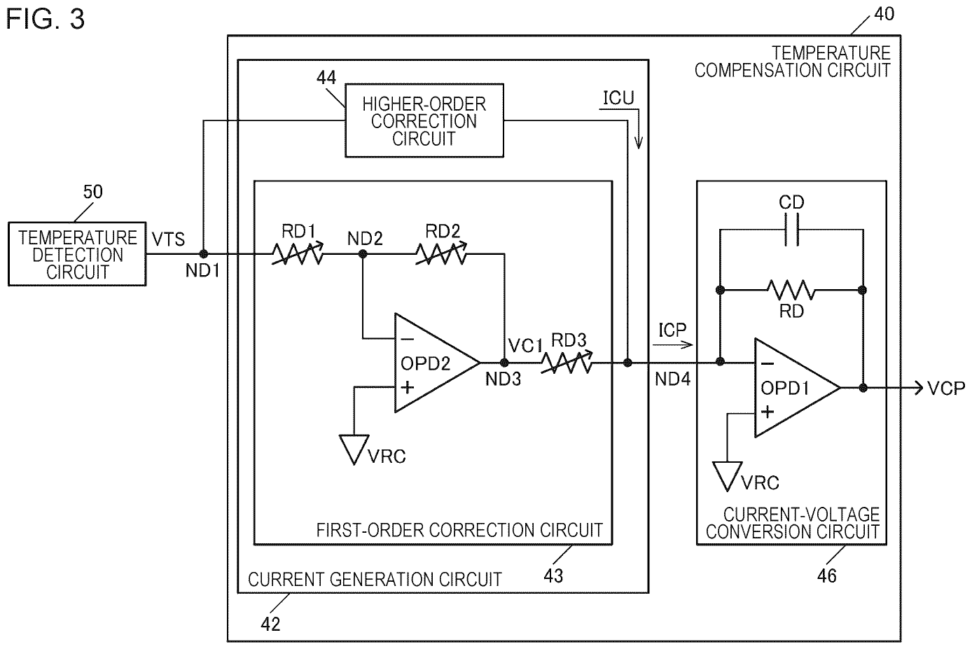

FIG. 3 shows a configuration example of the temperature compensation circuit 40. The configuration of the temperature compensation circuit 40 is not limited to the configuration of FIG. 3, and various modifications such as omitting some of the components, adding other components, and replacing some of the components with other components can be implemented.

The temperature compensation circuit 40 is a circuit that outputs the temperature compensation voltage VCP by polynomial approximation using the temperature as a variable. The temperature compensation circuit 40 includes a current generation circuit 42 and a current-voltage conversion circuit 46. The current generation circuit 42 generates a temperature compensation current ICP based on the temperature detection result of the temperature detection circuit 50. For example, the current generation circuit 42 generates a temperature compensation current ICP for temperature compensating the frequency-temperature characteristic of the resonator 10 based on the temperature detection voltage VTS which is the temperature detection result. The temperature compensation current ICP is also referred to as a function current. The current-voltage conversion circuit 46 converts the temperature compensation current ICP from the current generation circuit 42 into a voltage and outputs the temperature compensation voltage VCP. Specifically, the current-voltage conversion circuit 46 outputs the temperature compensation voltage VCP by using an operational amplifier OPD1.

The current generation circuit 42 includes a first-order correction circuit 43 and a higher-order correction circuit 44. The first-order correction circuit 43 and the higher-order correction circuit 44 are also referred to as a first-order compensation circuit and a higher-order compensation circuit. The first-order correction circuit 43 outputs a first-order current that approximates a first-order function based on the temperature detection voltage VTS. For example, the first-order correction circuit 43 outputs a first-order current based on the first-order correction data corresponding to a first-order coefficient of a polynomial in the polynomial approximation. The higher-order correction circuit 44 outputs, based on the temperature detection voltage VTS, a higher-order current ICU that approximates the higher-order function to the current-voltage conversion circuit 46. For example, the higher-order correction circuit 44 outputs a higher-order current ICU based on the higher-order correction data corresponding to the higher-order coefficient of the polynomial in the polynomial approximation. The current obtained by adding the higher-order current ICU and the first-order current obtained by the first-order correction circuit 43 is input to the current-voltage conversion circuit 46 as the temperature compensation current ICP.

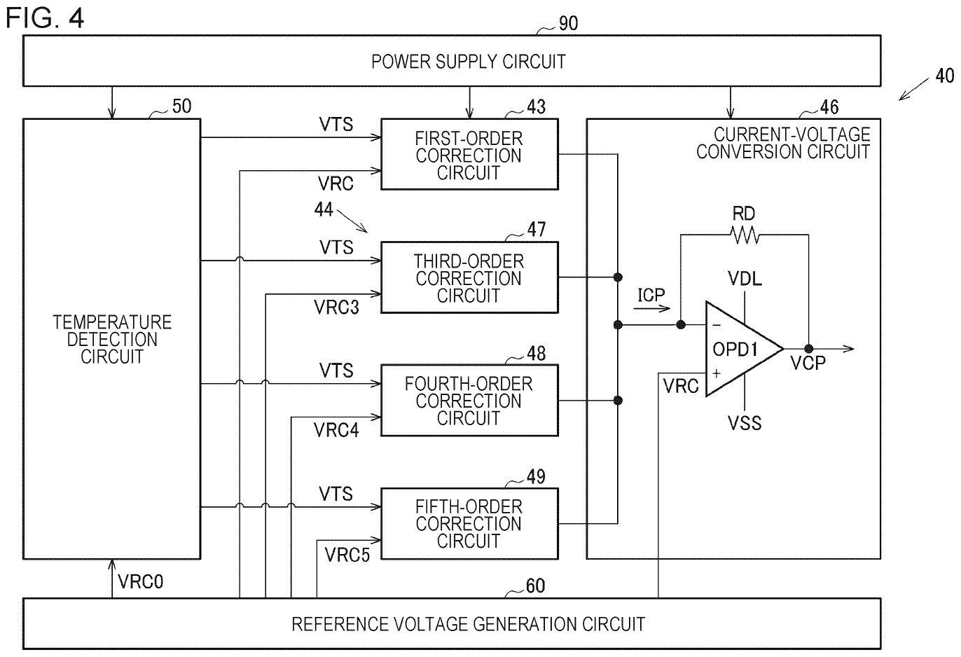

FIG. 4 shows a configuration example of the higher-order correction circuit 44. In FIG. 4, the higher-order correction circuit 44 includes a third-order correction circuit 47, a fourth-order correction circuit 48, and a fifth-order correction circuit 49. The higher-order correction circuit 44 may include a second-order correction circuit or a sixth-order or higher correction circuit. The third-order correction circuit 47 outputs a third-order current that approximates a third-order function. Similarly, the fourth-order correction circuit 48 and the fifth-order correction circuit 49 output a fourth-order current that approximates a fourth-order function and a fifth-order current that approximates a fifth-order function, respectively. The temperature detection voltage VTS from the temperature detection circuit 50 and the reference voltage VRC from the reference voltage generation circuit 60 are input to the first-order correction circuit 43. In addition, the temperature detection voltages VTS from the temperature detection circuit 50 and reference voltages VRC3, VRC4, and VRC5 from the reference voltage generation circuit 60 are input to the third-order correction circuit 47, the fourth-order correction circuit 48, and the fifth-order correction circuit 49. The reference voltage generation circuit 60 outputs a reference voltage VRC0 to the temperature detection circuit 50.

For example, each of the third-order correction circuit 47, the fourth-order correction circuit 48, and the fifth-order correction circuit 49 includes a differential circuit. The differential circuit includes a first transistor and a second transistor provided in parallel between a high potential side power supply node and a first node and constituting a differential pair, and a current source transistor provided between the first node and a low potential side power supply node and through which a bias current that is a reference current flows. The temperature detection voltage VTS is input to a gate of the first transistor of the differential pair, and the reference voltage VRC3, VRC4, or VRC5 is input to a gate of the second transistor of the differential pair.

As shown in FIG. 3, the first-order correction circuit 43 includes an operational amplifier OPD2 and resistors RD1 and RD2. In addition, the first-order correction circuit 43 can include a resistor RD3 having a variable resistance value. The operational amplifier OPD2 receives the reference voltage VRC at a non-inverting input terminal. The resistor RD1 is provided between an input node ND1 of the temperature detection voltage VTS and a node ND2 of the inverting input terminal of the operational amplifier OPD2. The resistor RD2 is provided between the node ND2 and a node ND3 of an output terminal of the operational amplifier OPD2. The resistor RD3 is provided between the node ND3 and an output node ND4 of the current generation circuit 42.

The current-voltage conversion circuit 46 outputs the temperature compensation voltage VCP by converting the temperature compensation current ICP, which is the sum of the first-order current and the higher-order current ICU, into a current voltage. Accordingly, the temperature compensation voltage VCP that approximates the polynomial function is generated. Specifically, the current-voltage conversion circuit 46 includes the operational amplifier OPD1 and a feedback resistor RD. The operational amplifier OPD1 receives the reference voltage VRC at the non-inverting input terminal, and the output node ND4 of the current generation circuit 42 is coupled to an inverting input terminal. The resistor RD is provided between an output terminal of the operational amplifier OPD1 and the inverting input terminal of the operational amplifier OPD1. In FIG. 3, a capacitor CD for phase compensation is provided between the output terminal and the inverting input terminal of the operational amplifier OPD1, but as shown in FIG. 4, the capacitor CD may not be provided.

As described above, the temperature compensation circuit 40 in FIG. 3 includes the first-order correction circuit 43 and the higher-order correction circuit 44 to which the temperature detection voltage VTS is input, the current generation circuit 42 that generates a temperature compensation current ICP by using the first-order correction circuit 43 and the higher-order correction circuit 44, and the current-voltage conversion circuit 46 that converts the temperature compensation current ICP into a voltage and outputs the temperature compensation voltage VCP. According to the temperature compensation circuit 40 having such a configuration, the temperature compensation current ICP, which is a function current generated by the current generation circuit 42 based on the temperature detection voltage VTS, can be converted into a voltage by the current-voltage conversion circuit 46 and can be output as a temperature compensation voltage VCP.

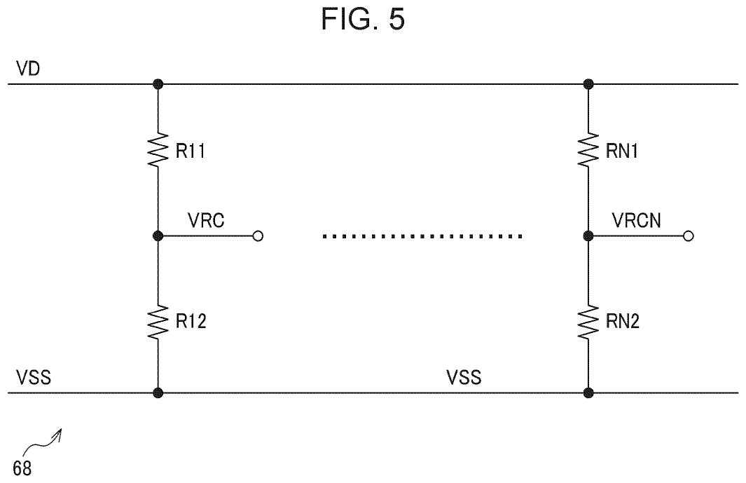

FIG. 5 shows a configuration example of the voltage generation circuit 68 provided in the reference voltage generation circuit 60. The voltage generation circuit 68 generates reference voltages VRC to VRCN by voltage-dividing the reference power supply voltage VD by using a resistor circuit. For example, in FIG. 5, a reference voltage VRC is generated by voltage-dividing the reference power supply voltage VD with a resistor circuit configured by a resistor R11 and a resistor R12. In addition, a reference voltage VRCN is generated by voltage-dividing the reference power supply voltage VD with a resistor circuit configured by a resistor RN1 and a resistor RN2. Here, the reference power supply voltage VD is a voltage VRF generated by a reference circuit such as a BGR circuit as described later, or a voltage generated by the regulator based on the voltage VRF.

### 2. Reference Voltage Generation Circuit and Power Supply Circuit

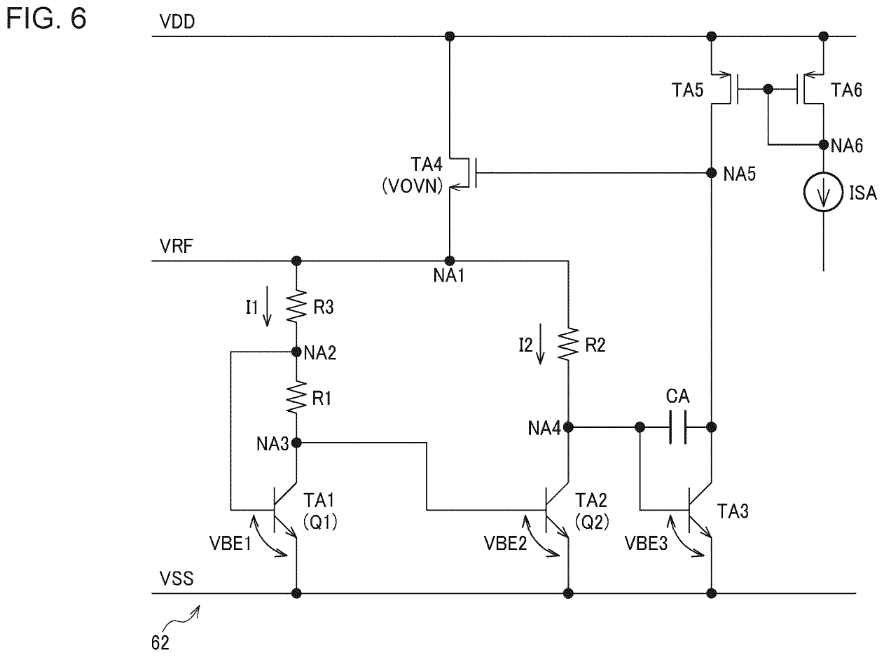

FIG. 6 shows a configuration example of the reference circuit 62 provided in the reference voltage generation circuit 60. The reference circuit 62 is a bandgap reference circuit (BGR circuit), and more specifically, a Widlar type BGR circuit. The reference circuit 62 includes npn bipolar transistors TA1, TA2, and TA3, the resistors R1, R2, and R3, an N-type MOS transistor TA4, P-type MOS transistors TA5 and TA6, and a capacitor CA. The configuration of the reference circuit 62 is not limited to the configuration of FIG. 6, and various modifications such as omitting some of the components, adding other components, and replacing some of the components with other components can be implemented.

The resistors R3 and R1 and the bipolar transistor TA1 are provided in series between a node NA1 of the voltage VRF and a node of VSS (GND). Then, in the bipolar transistor TA1, a base is coupled to a node NA2 between the resistor R3 and the resistor R1, a collector is coupled to a node NA3 at one end of the resistor R1, and an emitter is coupled to the node of VSS.

In addition, the resistor R2 and the bipolar transistor TA2 are provided in series between the node NA1 of the voltage VRF and the node of VSS. Then, in the bipolar transistor TA2, a base is coupled to the node NA3, a collector is coupled to a node NA4 at one end of the resistor R2, and an emitter is coupled to the node of VSS. In the bipolar transistor TA3, a base is coupled to the node NA4, a collector is coupled to a node NA5, and an emitter is coupled to the node of VSS. The capacitor CA is provided between the node NA4 and the node NA5.

The N-type transistor TA4 is provided between a node of VDD and the node NA1, and a gate is coupled to the node NA5. The P-type transistors TA5 and TA6 constitute a current mirror circuit, and a current of a current source ISA coupled to a drain of the transistor TA6 is mirrored to the transistor TA5 and flows to the bipolar transistor TA3.

For example, when a collector current of the bipolar transistor is IC and the saturation current is IS, a base-emitter voltage is represented by VBE=(kT/q) ln(IC/IS)=VT·ln(IC/IS). Here, k is a Boltzmann constant, T is a temperature, and q is an electric charge of an electron. In addition, when the number of parallel bipolar transistors is represented by Q, the saturation current is represented by IS=Q·IS0.

Here, the number of parallel bipolar transistor TA1 and that of the bipolar transistor TA2 in FIG. 6 are defined as Q1 and Q2, respectively, and the collector currents IC flowing through the bipolar transistors TA1 and TA2 are defined as I1 and I2, respectively. Then, a base-emitter voltage of the bipolar transistor TA1 is represented by VBE1=VT·ln{I1/(Q1·IS0)}, and a base-emitter voltage of the bipolar transistor TA2 is represented by VBE2=VT·ln{I2/(Q2·IS0)}. Therefore, when ΔVBE=VBE1−VBE2, ΔVBE=VT·ln{(Q2/Q1). (I1/I2)} is represented.

Since a voltage across the resistor R1 is VBE1−VBE2=ΔVBE, I1=ΔVBE/R1. Therefore, the voltage VRF=VBE1+I1·R3 is represented as in the following Equation (1). In the present embodiment, the resistor and the resistance value thereof are represented by the same reference sign. For example, the resistance values of the resistors R1, R2, and R3 are also represented as R1, R2, and R3.

$$\begin{matrix}V R F = V B E 1 + \frac{R 3}{R 1} Δ V B E \\ = V B E 1 + \frac{R 3}{R 1} \cdot V T \cdot ln ( \frac{Q 2}{Q 1} \cdot \frac{I 1}{I 2} )\end{matrix} \qquad ( 1 )$$

The first term VBE1 of the above-described Equation (1) has a negative temperature characteristic. On the other hand, the second term (R3/R1) ΔVBE has a positive temperature characteristic. Since the first term VBE1 is determined as a physical quantity, it is possible to cancel the negative temperature characteristic of the first term by adjusting the second term. As a result, it is possible to generate a voltage VRF having a flat temperature characteristic with a minimum fluctuation in the usage temperature range. By canceling the negative temperature characteristic of the first term of the above Equation (1) with the positive temperature characteristic of the second term in this manner, the voltage VRF when the voltage VRF has a flat temperature characteristic is about 1.25 V. That is, by adjusting the voltage VRF to be around 1.25, it is possible to generate the voltage VRF having a flat temperature characteristic. The adjustment of the voltage VRF is performed by adjusting the resistance value of R3 in the second term of the above Equation (1) and the like. When the adjusted voltage VRF is lower than 1.25 V, VRF has a negative temperature characteristic, and when the adjusted voltage VRF exceeds 1.25 V, VRF has a positive temperature characteristic.

Here, when a threshold voltage of the transistor is defined as Vth, a gate-source voltage is defined as VGS, and a drain-source voltage is defined as VDS, an overdrive voltage can be expressed as VOV=VGS−Vth, and is an index indicating how much VGS exceeds Vth. In order to operate a transistor in the saturation region, VDS>VOV is required.

Then, as described above, when the voltage of VRF has a flat temperature characteristic, the voltage of VRF is about 1.25 V. In addition, when an overdrive voltage of the N-type transistor TA4 is defined as VOVN, the overdrive voltage VOVN for operating the transistor TA4 in the saturation region is about 0.1 to 0.2 V. Therefore, in order to output the voltage VRF having a flat temperature characteristic to the reference circuit 62 of FIG. 6, it is necessary to set a supplied power supply voltage to be about VDD>VRF+VOVN=1.35 V to 1.45 V. Therefore, when the lower limit of VDD is, for example, 1.1 V or the like due to the lowering of the power supply voltage, the reference circuit 62 of FIG. 6 has a problem that the low noise and flat temperature characteristics voltage VRF cannot be generated.

The reason why the bipolar transistor TA3 is further provided in FIG. 6 is to perform a first role of determining an operating point of the bipolar transistor TA2 and a second role of adjusting the load current flowing through the load circuit to which the voltage VRF is supplied. That is, by providing the bipolar transistor TA3, it is possible to prevent a collector-emitter voltage of the bipolar transistor TA2 from decreasing and to operate the bipolar transistor TA2 in an active region. Accordingly, the above-described first role is realized. In addition, when a load current IL of VRF flows, the gate voltage of the transistor TA4 is adjusted by the bipolar transistor TA3, and feedback is applied so that the voltage VRF becomes constant. Accordingly, the above-described second role is realized. For example, when the bipolar transistor TA3 operates in the active region, VBE3, which is the base-emitter voltage of the bipolar transistor TA3, becomes constant. Therefore, even when the load current IL changes, a current I2 flowing through the bipolar transistor TA2 does not change, and the increase in the load current IL flows from the transistor TA4.

For example, when a current flowing through the transistor TA4 is defined as ITA4, ITA4=I1+I2+IL. In the reference circuit 62 of FIG. 6, when the bipolar transistors TA1, TA2, and TA3 operate in the active region and the transistor TA4 operates in the saturation region, a current I1 and the current I2 are uniquely determined, and thus the voltage VRF is constant.

That is, when the load current IL increases, the gate voltage VG of the transistor TA4 increases by the feedback using the bipolar transistor TA3, and VG-VRF, which is the gate-source voltage of the transistor TA4, increases. Accordingly, the increase in the load current IL flows to the transistor TA4. On the other hand, when the load current IL decreases, the gate voltage VG decreases, the gate-source voltage VG-VRF also decreases, and the current flowing through the transistor TA4 also decreases. Accordingly, the voltage VRF is kept constant even when the load current IL changes.

For example, there is a type of circuit that performs feedback control using an operational amplifier (op-amp) as a BGR circuit, but when an operational amplifier is used, noise of the voltage VRF increases. On the other hand, in the Widlar type BGR circuit of FIG. 6, since the feedback control is performed without using the operational amplifier, it is possible to generate the voltage VRF having low noise. In addition, as described above, even when the load current IL changes, the voltage VRF can be kept constant, and a low output impedance can be realized.

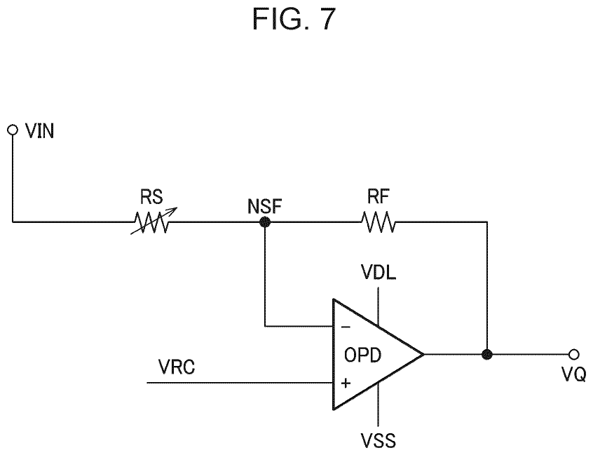

FIG. 7 shows a configuration example of the amplifier circuit. The amplifier circuit is an inverting amplifier circuit, and includes an operational amplifier OPD that operates with a power supply voltage VDL supplied as power, and resistors RS and RF. The operational amplifier OPD corresponds to, for example, the operational amplifier OPD1 of FIG. 3, and the resistors RS and RF correspond to the resistors RD3 and RD of FIG. 3. The resistors RS and RF are provided in series between an input node of a voltage VIN and an output terminal of the operational amplifier OPD. In addition, the operational amplifier OPD receives the reference voltage VRC at a non-inverting input terminal, has a coupling node NSF between the resistor RS and the resistor RF coupled to the inverting input terminal, and outputs an output voltage VQ from the output terminal. The non-inverting input terminal is a first input terminal, and the inverting input terminal is a second input terminal.

The output voltage VQ of the amplifier circuit of FIG. 7 is represented by the following Equation (2).

$$V Q = - \frac{R F}{R S} V I N + ( 1 + \frac{R F}{R S} ) V R C \qquad ( 2 )$$

As is clear from the above-described Equation (2), noise of the reference voltage VRC is multiplied by (1+RF/RS). Therefore, in order to make the output voltage VQ corresponding to the temperature compensation voltage VCP of FIG. 3 low in noise, the reference voltage VRC needs to be a low-noise voltage.

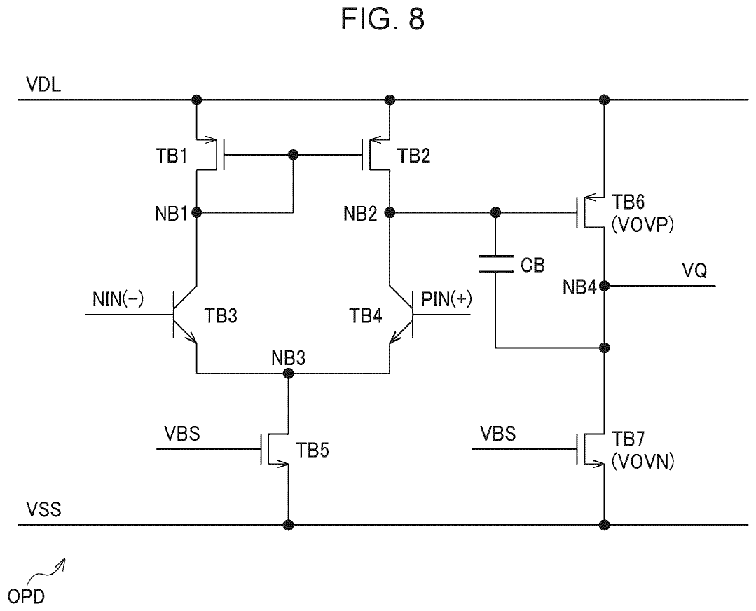

FIG. 8 is a circuit configuration example of the operational amplifier OPD. A differential portion of the operational amplifier OPD of FIG. 8 includes transistors TB1 and TB2 that constitute a current mirror circuit, bipolar transistors TB3 and TB4 that are transistors of a differential pair, and a transistor TB5 that is a current source. The transistors TB1 and TB2 are provided between the node of VDL and nodes NB1 and NB2, and a gate is coupled to the node NB1. The bipolar transistor TB3 is provided between the node NB1 and the node NB3, and a voltage NIN from the inverting input terminal is input to the base. The bipolar transistor TB4 is provided between the node NB2 and the node NB3, and a voltage PIN from the non-inverting input terminal is input to the base. A modification using the MOS transistor instead of bipolar transistors TB3 and TB4 can be implemented. The transistor TB5 is provided between the node NB3 and the node of VSS, and a bias voltage VBS is input to the gate.

An output portion of the operational amplifier OPD includes transistors TB6 and TB7 provided in series between the node of VDL and the node of VSS. A gate of the transistor TB6 is coupled to the node NB2, which is the output node of the differential portion, and the bias voltage VBS is input to a gate of the transistor TB7. The output voltage VQ is output from the node NB4 between the transistor TB6 and the transistor TB7. A capacitor CB is a capacitor for phase compensation.

Here, an overdrive voltage of the P-type transistor TB6 of FIG. 8 is defined as VOVP, and an overdrive voltage of the N-type transistor TB7 is defined as VOVN. Then, a relationship of the following Equation (3) is established for the voltage range of the output voltage VQ of the amplifier circuit (operational amplifier OPD) of FIG. 7.

$$V O V N < V Q < V D L - V O V P \qquad ( 3 )$$

That is, a lower limit of the output voltage VQ is VOVN, and an upper limit of the output voltage VQ is VDL-VOVP. Therefore, when the power supply voltage VDL has a temperature characteristic, the voltage range of the output voltage VQ decreases. Therefore, it is desirable that the power supply voltage VDL has a flat temperature characteristic.

In this case, a method of generating a power supply voltage VDL by using the voltage VRF generated by the reference circuit 62 shown in FIG. 6 is considered. For example, the regulator generates a power supply voltage VDL using the voltage VRF as a reference voltage.

However, when the power supply voltage VDD from the outside is lowered, the voltage VRF generated by the reference circuit 62 of FIG. 6 does not have a flat temperature characteristic, as described above. Therefore, when the power supply voltage VDL is generated based on such a voltage VRF, the power supply voltage VDL does not have a flat temperature characteristic, and the voltage range of the output voltage VQ of the amplifier circuit of FIG. 7 decreases. Therefore, when the amplifier circuit of FIG. 7 is used as the current-voltage conversion circuit 46 of FIG. 3, the voltage range of the temperature compensation voltage VCP decreases, and a situation occurs in which temperature compensation cannot be performed.

Thus, as a method for addressing the problem in that a voltage range of the temperature compensation voltage VCP decreases, a method of increasing a capacitance of a variable capacitance element such as a varactor in the variable capacitance circuit 32 of FIG. 2 to increase sensitivity can also be considered. However, when the capacitance of the variable capacitance element is increased to increase the sensitivity in this way, the variation and fluctuation of the capacitance become large, which causes problems such as the complication of temperature compensation.

In addition, since the bandgap reference voltage, which is the voltage VRF generated by the reference circuit 62 of FIG. 6, is low noise, it is desirable that the power supply voltage VDL supplied by the power supply circuit 90 is generated based on the low-noise bandgap reference voltage. However, when the power supply voltage VDD is lowered, operation of the reference circuit 62 becomes severe, and when VDD is lower than, for example, 1.5 V to 1.6 V, the temperature characteristic of the voltage VRF cannot be made flat. Therefore, as the power supply voltage VDD is lowered, noise reduction and flattening of the temperature characteristic are in a trade-off relationship.

On the other hand, in the temperature compensation circuit 40 of FIG. 3, when noise of the reference voltage VRC input to the operational amplifiers OPD1 and OPD2 or the reference voltage (VRC3, VRC4, and VRC5 of FIG. 4) input to the higher-order correction circuit 44 increases, the large noise is amplified as described in the above Equation (2). Accordingly, the noise of the temperature compensation voltage VCP increases, and the frequency noise of the clock signal output by the oscillator 4 increases.

In addition, the temperature compensation circuit 40 generates a temperature compensation voltage VCP by using the operational amplifiers OPD1 and OPD2. Therefore, the power supply voltages VDL of the operational amplifiers OPD1 and OPD2 need to maintain high voltages over a wide temperature range. However, when the power supply voltage VDL has a positive or negative temperature characteristic, there is a possibility that the power supply voltage VDL decreases in a specific temperature range. For example, when the power supply voltage VDL has a negative temperature characteristic, the power supply voltage VDL decreases in a high-temperature range, and when the power supply voltage VDL has a positive temperature characteristic, the power supply voltage VDL decreases in a low-temperature range. As shown in the above Equation (3), VQ<VDL−VOVP. Therefore, when the power supply voltage VDL decreases, an upper limit of the output voltage VQ=VCP decreases, and the operational amplifiers OPD1 and OPD2 become unable to operate stably.

Therefore, in the present embodiment, as for the reference voltage of the temperature compensation circuit 40, the reference voltage generation circuit 60 generates a reference voltage VRC having low noise and supplies the reference voltage VRC to the temperature compensation circuit 40. For example, the reference voltage generation circuit 60 generates a reference voltage VRC having low noise by using the reference circuit 62 such as a BGR circuit, and supplies the reference voltage VRC to the temperature compensation circuit 40. On the other hand, as for the power supply voltage of the temperature compensation circuit 40, the power supply circuit 90 generates a power supply voltage VDL having a flat temperature characteristic and supplies the power supply voltage VDL to the temperature compensation circuit 40. For example, the power supply circuit 90 generates a power supply voltage VDL having a flat temperature characteristic using a reference circuit different from the BGR circuit, and supplies the power supply voltage VDL to the temperature compensation circuit 40.

In this way, the temperature compensation circuit 40 can generate a temperature compensation voltage VCP having low noise by using the reference voltage VRC having low noise, and thus it is possible to realize the low noise of the clock signal generated by the oscillation of the oscillation circuit 30. In addition, the operational amplifier or the like of the temperature compensation circuit 40 can be operated by being supplied with the power supply voltage VDL having a flat temperature characteristic. Therefore, for example, even when the power supply voltage VDD is lowered, it is possible to prevent a situation in which an output voltage range of the operational amplifier is narrowed and appropriate temperature compensation cannot be performed.

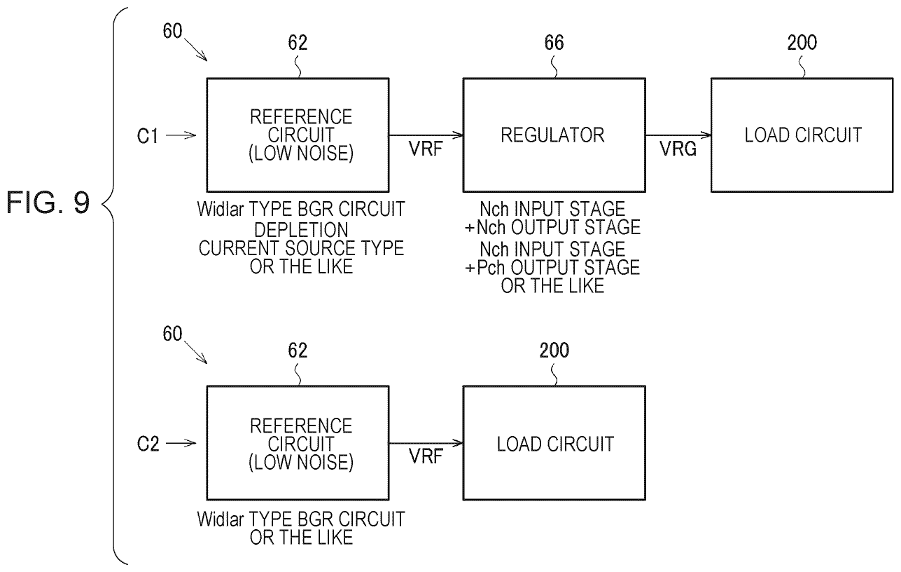

Next, a basic configuration of the reference voltage generation circuit 60 will be described with reference to FIG. 9. In C1 of FIG. 9, the reference voltage generation circuit 60 includes the reference circuit 62 and a regulator 66, the reference circuit 62 generates a voltage VRF having low noise, and the regulator 66 generates a voltage VRG based on the voltage VRF. For example, the regulator 66 generates a voltage VRG by regulating the power supply voltage VDD based on the voltage VRF. A reference voltage generated based on the voltage VRG is supplied to the temperature compensation circuit 40. Specifically, the voltage VRG from the regulator 66 is supplied to the voltage generation circuit 68 as a reference power supply voltage VD of FIG. 5, and reference voltages VRC to VRCN are generated. In C2 of FIG. 9, the reference voltage generation circuit 60 includes the reference circuit 62, the reference circuit 62 generates a voltage VRF having low noise, and a reference voltage generated based on the voltage VRF is supplied to the temperature compensation circuit 40. Specifically, the voltage VRF from the reference circuit 62 is supplied to the voltage generation circuit 68 of FIG. 5 as the reference power supply voltage VD, and the reference voltages VRC to VRCN are generated.

For example, in the configuration of C2 of FIG. 9, when an output impedance of the reference circuit 62 is high, there is a problem in that the voltage VRF changes due to the generation of the load current in the load circuit 200. In this regard, in the configuration of C1 in FIG. 9, a regulator 66 having a high input impedance and a low output impedance is provided. Therefore, even when the load current is generated, there is an advantage in that a stable voltage VRG or current can be supplied. On the other hand, when an output impedance of the reference circuit 62 is low, by adopting a configuration as shown in C2 of FIG. 9, the regulator 66 can be omitted, thereby making it possible to achieve circuit miniaturization.

As the reference circuit 62 shown in C1 of FIG. 9, the Widlar type BGR circuit of FIG. 6 or a depletion current source type circuit can be used. The depletion current source type circuit is a reference circuit using a depletion-type transistor. In addition, as the regulator 66, a regulator with an Nch output stage and an Nch input stage as will be described later, a regulator with a Pch output stage and an Nch input stage, or the like can be used. In addition, as the reference circuit 62 shown in C2, the Widlar type BGR circuit of FIG. 6 or the like can be used.

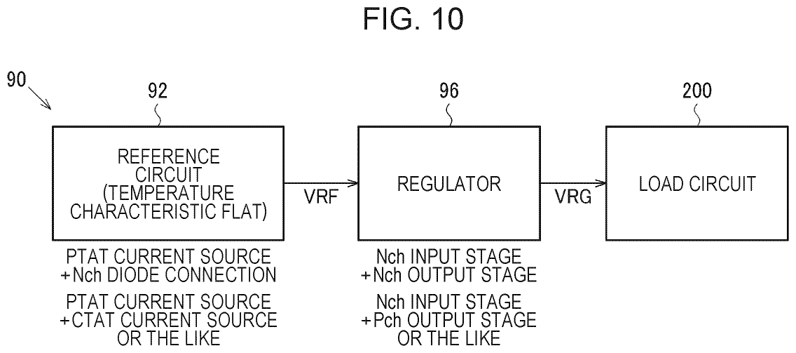

FIG. 10 shows a basic configuration of the power supply circuit 90. In FIG. 10, the power supply circuit 90 includes a reference circuit 92 and a regulator 96. The reference circuit 92 generates a voltage VRF having a flat temperature characteristic, and the voltage VRG generated by the regulator 96 based on the voltage VRF is supplied to the temperature compensation circuit 40 as the power supply voltage VDL. For example, the regulator 96 generates a power supply voltage VDL by regulating the power supply voltage VDD based on the voltage VRF, and supplies the power supply voltage VDL to the temperature compensation circuit 40.

As the reference circuit 92 of FIG. 10, a circuit using a later-described PTAT current source and an Nch diode-connected transistor, or a circuit using the PTAT current source and a CTAT current source can be used. PTAT is an abbreviation for Proportional To Absolute Temperature, and CTAT is an abbreviation for Complementary To Absolute Temperature. The PTAT current is a current that increases with a rise in temperature, and the CTAT current is a current that decreases with a rise in temperature. In addition, as the regulator 96, a regulator with an Nch output stage and an Nch input stage, a regulator with a Pch output stage and an Nch input stage, or the like can be used.

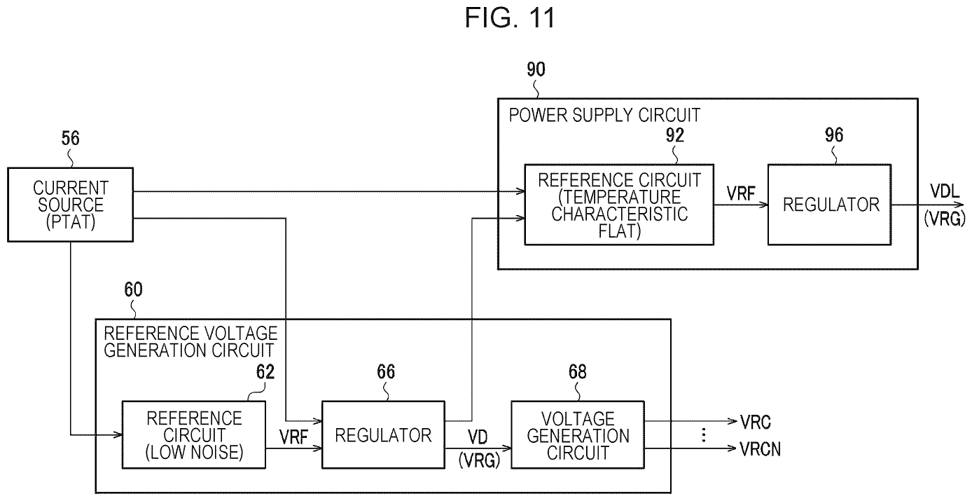

FIG. 11 shows a configuration example of the reference voltage generation circuit 60 and the power supply circuit 90. A current source 56 is a current source for causing the PTAT current, which increases with the rise in temperature, to flow to the reference circuit 62 and the regulator 66 of the reference voltage generation circuit 60, and the reference circuit 92 of the power supply circuit 90.

The reference voltage generation circuit 60 includes the reference circuit 62, the regulator 66, and the voltage generation circuit 68. The reference circuit 62 generates a voltage VRF having low noise, which is a BGR voltage, as described in FIG. 6. The regulator 66 generates a voltage VRG as the reference power supply voltage VD of FIG. 5 by regulating the power supply voltage VDD based on the voltage VRF. The voltage generation circuit 68 generates reference voltages VRC to VRCN based on the reference power supply voltage VD. As shown in C2 of FIG. 9, the voltage generation circuit 68 may generate reference voltages VRC to VRCN using the voltage VRF from the reference circuit 62 as the reference power supply voltage VD. As shown in FIG. 4, the temperature compensation circuit 40 generates a temperature compensation voltage VCP based on the reference voltages VRC to VRCN. In the present embodiment, the reference voltages VRC to VRCN are represented as a reference voltage VRC as appropriate.

The power supply circuit 90 includes the reference circuit 92 and the regulator 96. The reference circuit 92 generates a voltage VRF having a flat temperature characteristic. A specific configuration example of the reference circuit 92 will be described later. The regulator 96 generates a voltage VRG by regulating, for example, the power supply voltage VDD based on the voltage VRF. The regulator 96 supplies the voltage VRG to the temperature compensation circuit 40 as the power supply voltage VDL.

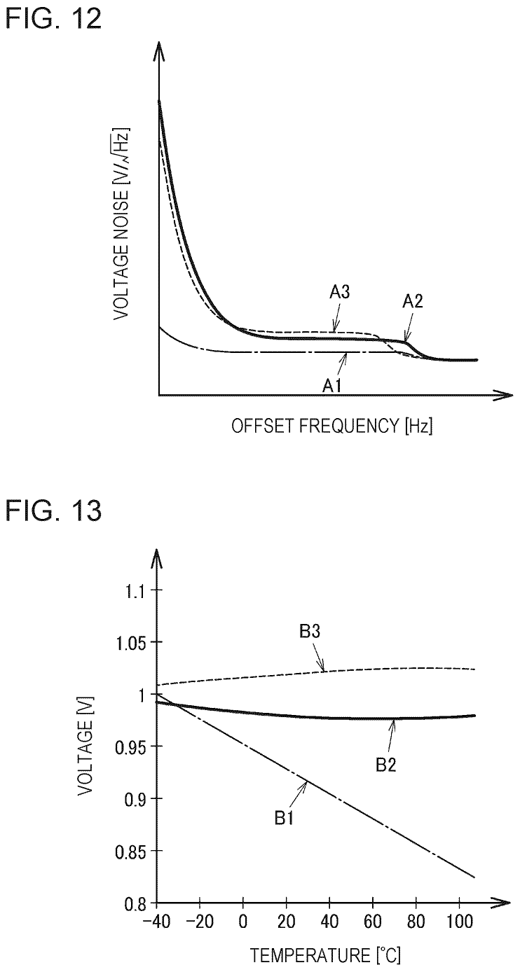

FIG. 12 is a diagram showing an example of a noise characteristic of the voltage VRG, which is the regulated voltage. A1 of FIG. 12 is a noise characteristic of the voltage VRG generated by the regulator 66 of the reference voltage generation circuit 60. In the reference voltage generation circuit 60, as shown in FIG. 6, the reference circuit 62 generates a BGR voltage having low noise as the voltage VRF. Therefore, as shown in A1, the voltage VRG generated based on the voltage VRF, which is the BGR voltage, becomes a low noise voltage, and the reference voltage VRC generated based on the voltage VRG also becomes a low noise voltage.

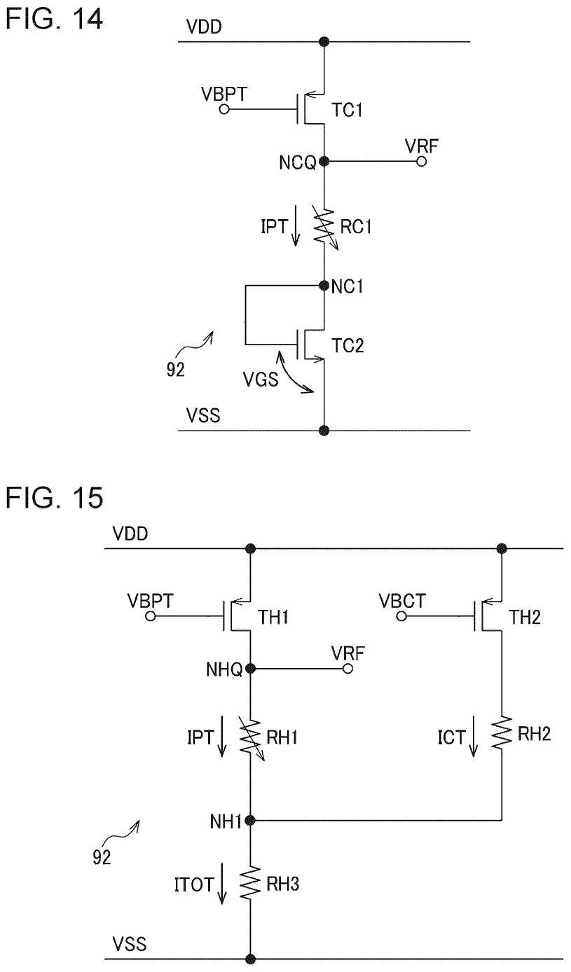

A2 and A3 of FIG. 12 are noise characteristics of the voltage VRG generated by the regulator 96 of the power supply circuit 90. The regulator 96 generates a voltage VRG based on the voltage VRF generated by the reference circuit 92, which will be described later with reference to FIGS. 14 and 15 and supplies the voltage VRG to the temperature compensation circuit 40 as the power supply voltage VDL. A2 of FIG. 12 is a noise characteristic of the voltage VRG based on the voltage VRF of the reference circuit 92 of FIG. 14, and A3 is a noise characteristic of the voltage VRG based on the voltage VRF of the reference circuit 92 of FIG. 15. The voltage VRF generated by the reference circuit 92 of the power supply circuit 90 has larger noise than the voltage VRF generated by the reference circuit 62 of the reference voltage generation circuit 60. Therefore, the voltage VRG generated by the regulator 96 based on the voltage VRF has greater noise than that in A1 as shown in A2 and A3 of FIG. 12.

FIG. 13 is a diagram showing an example of a temperature characteristic of the voltage VRG, which is the regulated voltage. B1 of FIG. 13 is a temperature characteristic of the voltage VRG generated by the regulator 66 of the reference voltage generation circuit 60. The reference circuit 62 generates a BGR voltage as the voltage VRF, but as described in FIG. 6, when the power supply voltage VDD becomes a low voltage, the reference circuit 62 cannot generate the voltage VRF having a flat temperature characteristic. That is, when the power supply voltage VDD is high, the negative temperature characteristic of the first term in the above Equation (1) is canceled by the positive temperature characteristic of the second term, and the flat temperature characteristic voltage VRF having a constant voltage in the usage temperature range can be generated. For example, when the voltage VRF has a flat temperature characteristic, the voltage VRF is about 1.25 V. However, when the power supply voltage VDD decreases, the voltage VRF generated by the reference circuit 62 becomes, for example, a negative temperature characteristic. Therefore, as shown in B1 of FIG. 13, the voltage VRG generated by the regulator 66 based on the voltage VRF also has a negative temperature characteristic.

B2 and B3 of FIG. 13 are temperature characteristics of the voltage VRG generated by the regulator 96 of the power supply circuit 90. B2 of FIG. 13 is a temperature characteristic of the voltage VRG based on the voltage VRF of the reference circuit 92 of FIGS. 14, and B3 is a temperature characteristic of the voltage VRG based on the voltage VRF of the reference circuit 92 of FIG. 15. The regulator 96 generates a voltage VRG based on the voltage VRF generated by the reference circuit 92, which will be described later with reference to FIGS. 14 and 15 and supplies the voltage VRG to the temperature compensation circuit 40 as the power supply voltage VDL. Then, the voltage VRF generated by the reference circuit 92 of the power supply circuit 90 has a flat temperature characteristic as compared with the voltage VRF generated by the reference circuit 62 of the reference voltage generation circuit 60. Therefore, the voltage VRG generated by the regulator 96 based on the voltage VRF also has a flat temperature characteristic as compared with B1, as shown in B2 and B3 of FIG. 13. For example, the temperature characteristics of B2 and B3 are 0.3 mV/° C. or less, and even in a temperature range of −40° C. to 130° C., the voltage fluctuation is 50 mV or less.

As described above, in the present embodiment, the reference voltage generation circuit 60 generates a reference voltage VRC by using the voltage VRG having lower noise than the A2 and A3, as shown in A1 of FIG. 12. On the other hand, the power supply circuit 90 generates a power supply voltage VDL by using the voltage VRG having a flat temperature characteristic as compared with B1, as shown in B2 and B3 of FIG. 13. Therefore, even when noise reduction and a flat temperature characteristic are in a trade-off relationship due to a reduction in the power supply voltage VDD, it becomes possible to supply a voltage having low noise for the reference voltage VRC to the temperature compensation circuit 40, and to supply a voltage having a flat temperature characteristic for the power supply voltage VDL to the temperature compensation circuit 40.

For example, when the power supply voltage VDL of the temperature compensation circuit 40 is generated based on the voltage generated by the reference circuit 62 of FIG. 6, a power supply voltage VDL is generated by using a voltage that is equal to or less than 0.85 V at 100° C., for example, as shown in B1 of FIG. 13. Therefore, it becomes difficult to properly operate the operational amplifier of the temperature compensation circuit 40, a voltage range of the temperature compensation voltage VCP decreases, and appropriate temperature compensation cannot be realized. In contrast, the voltage VRG that is 0.95 V or higher even at 100° C. in the flat temperature characteristics of B2 and B3 can be used as the power supply voltage VDL. Therefore, the operational amplifier of the temperature compensation circuit 40 can be operated properly, and it is possible to prevent a situation in which the voltage range of the temperature compensation voltage VCP decreases and temperature compensation cannot be realized.

FIG. 14 is a configuration example of the reference circuit 92 of the power supply circuit 90. FIG. 14 shows a PTAT type reference circuit 92, and corresponds to the configuration example of the PTAT current source+Nch diode connection described in FIG. 10. The reference circuit 92 of FIG. 14 includes a transistor TC1, a resistor RC1, and a transistor TC2 provided in series between a node of VDD and a node of VSS. The transistor TC1 is a P-type MOS transistor, is provided between the node of VDD and the node NC1, and a bias voltage VBPT for PTAT is input to the gate. The bias voltage VBPT is controlled by, for example, the current source 56 of PTAT of FIG. 11, and thus a current IPT of PTAT flows through the resistor RC1. The resistor RC1 is provided between the node of VDD and the node NC1 in series with the transistor TC1 and is a resistor having a variable resistance value. The voltage VRF output from an output node NCQ is adjusted based on a resistance value of the resistor RC1. The transistor TC2 is an N-type MOS transistor, and a gate and a drain are coupled to the node NC1. That is, the N-type transistor TC2 is diode-connected.

In the reference circuit 92 of FIG. 14, when a gate-source voltage of the transistor TC2 is defined as VGS and the resistance value of the resistor RC1 is represented by RC1 having the same reference signs, the voltage of VRF=VGS+RC1. IPT is output from the output node NCQ.

Here, since VGS of the diode-connected transistor TC2 becomes the threshold voltage Vth of the transistor TC2, VGS=Vth has a negative temperature characteristic. Since the current IPT of PTAT has a positive temperature characteristic, the voltage VRF having a flat temperature characteristic can be generated by adjusting the resistance value of RC1. For example, VGS=Vth=about 0.4 V, and RC1·IPT when adjusted to have a flat temperature characteristic becomes about 0.2 V. Therefore, the voltage VRF generated by the reference circuit 92 becomes about 0.6 V, and as compared with the reference circuit 62 of FIG. 6, it is possible to generate the voltage VRF having a flat temperature characteristic. However, it is required to adjust the process variation.

FIG. 15 is also a configuration example of the reference circuit 92 of the power supply circuit 90. FIG. 15 shows a PTAT+CTAT type reference circuit 92, and corresponds to the configuration example of the PTAT current source+CTAT current source described in FIG. 10. The reference circuit 92 of FIG. 15 includes transistors TH1 and TH2 and resistors RH1, RH2, and RH3. The transistor TH1 and the resistor RH1 are provided in series between the node of VDD and a node NH1. In addition, the transistor TH2 and the resistor RH2 are provided in parallel with the transistor TH1 and the resistor RH1 and in series between the node of VDD and the node NH1. The resistor RH3 is provided between the node NH1 and the node of VSS.

The transistors TH1 and TH2 are P-type MOS transistors. A bias voltage VBPT for PTAT is input to the gate of the transistor TH1. Accordingly, the current IPT that increases with the rise in temperature flows through the resistor RH1. Here, in FIG. 15, a resistance value of the resistor RH1 is variable. In addition, a bias voltage VBCT for CTAT is input to a gate of the transistor TH2. Accordingly, the current ICT that decreases with the rise in temperature flows through the resistor RH2. A current of ITOT=IPT+ICT flows through the resistor RH3.

In the reference circuit 92 of FIG. 15, the voltage VRF of VRF=RH1·IPT+RH3. (IPT+ICT)=RH1. IPT+RH3. ITOT is output from an output node NHQ between the transistor TH1 and the resistor RH1. Since the current IPT has a positive temperature characteristic and the current ICT has a negative temperature characteristic, a voltage VRF having a flat temperature characteristic can be generated by adjusting the resistance value of the resistor RH1. Although the noise is lowered by changing the resistor RH3 of FIG. 15 to an N-type MOS transistor, the current balance adjustment becomes slightly difficult.

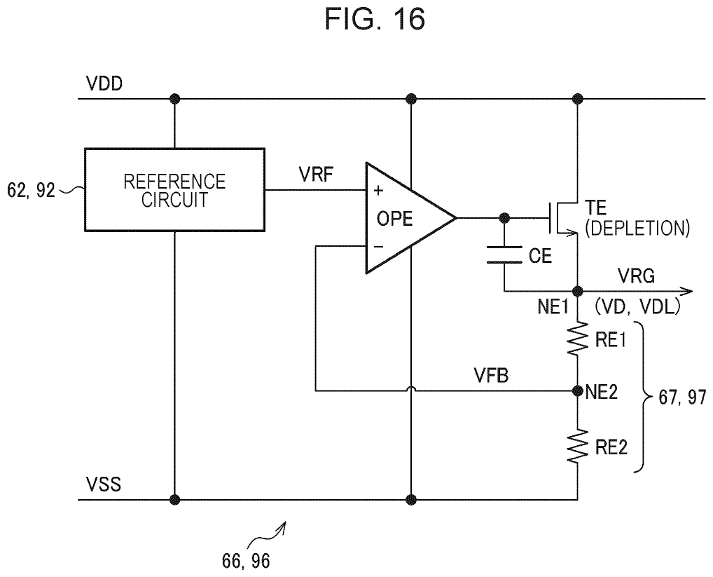

In the reference circuit 92 of FIG. 14, for example, the VRF having a low voltage such as 0.6 V is generated, whereas in the reference circuit 92 of FIG. 15, there is an advantage in that the VRF having a high voltage can be generated as compared with FIG. 14. For example, as shown in FIG. 16, which will be described later, the voltage VRF is input to the operational amplifier OPE of the regulator 96, but the input of the operational amplifier OPE has an input lower limit voltage. Then, when the voltage VRF is too low, there is a possibility that the voltage falls below this input lower limit voltage, however, using the reference circuit 92 of FIG. 15, such a situation can be prevented.

FIG. 16 shows a configuration example of the regulators 66 and 96 of FIG. 11. The regulator 66 includes the operational amplifier OPE, a transistor TE, and a voltage division circuit 67. The regulator 96 includes the operational amplifier OPE, the transistor TE, and a voltage division circuit 97.

In the operational amplifier OPE, the voltage VRF is input to the non-inverting input terminal, which is the first input terminal, and a feedback voltage VFB is input to the inverting input terminal, which is the second input terminal. The transistor TE is provided between the node of VDD, which is a first power supply node, and the output node NE1 of the voltage VRG, and the output of the operational amplifier OPE is input to the gate. In FIG. 16, a depletion N-type transistor is used as the transistor TE. However, a P-type transistor may be used as the transistor TE.

The voltage division circuits 67 and 97 are provided between the output node NE1 of the voltage VRG and the node of VSS, which is the second power supply node, and generate a voltage obtained by dividing the voltage VRG as the feedback voltage VFB. For example, the voltage division circuits 67 and 97 include resistors RE1 and RE2 provided in series between the output node NE1 and the node of VSS. The feedback voltage VFB from a node NE2 between the resistor RE1 and the resistor RE2 is input to the inverting input terminal of the operational amplifier OPE.

With the regulators 66 and 96 of FIG. 16, a voltage of VRG={(RE1+RE2)/RE2}VRF is output. The voltage VRG output by the regulator is the reference power supply voltage VD of FIG. 5 when the regulator is the regulator 66 of the reference voltage generation circuit 60, and is the power supply voltage VDL when the regulator is the regulator 96 of the power supply circuit 90.

The regulators 66 and 96 of FIG. 16 correspond to the regulators of the Nch input stage+Nch output stage of FIGS. 9 and 10. In the operational amplifier OPE of FIG. 16, the transistors of the differential pair of the differential portion are N-type MOS transistors or npn bipolar transistors, and thus low noise can be realized. In addition, since the transistor TE of the output portion is also a depletion N-type transistor, low noise can be realized. In this case, a P-type transistor may be used as the transistor TE. When the transistor TE is P-type, the regulators 66 and 96 of FIG. 16 correspond to the regulators of the Nch input stage+Pch output stage in FIGS. 9 and 10.

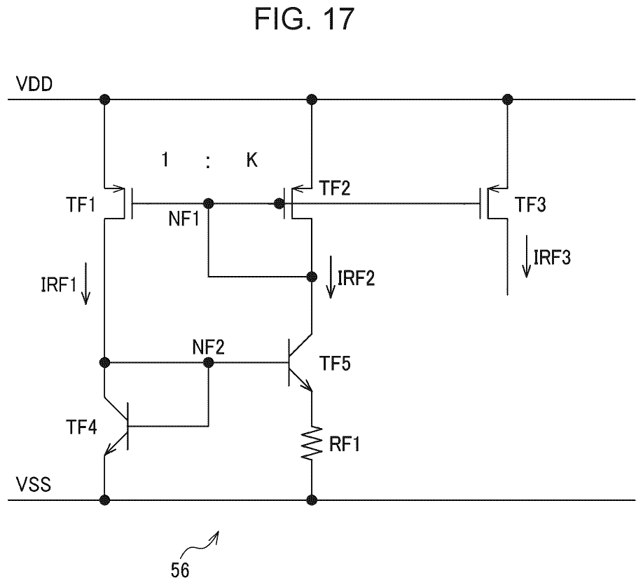

FIG. 17 shows a configuration example of a circuit of the current source 56 of PTAT of FIG. 11. The current source 56 of FIG. 17 includes transistors TF1, TF2, and TF3 that constitute a current mirror circuit, bipolar transistors TF4 and TF5, and a resistor RF1. Gates of the P-type transistors TF1, TF2, and TF3 are commonly coupled. A size ratio of the transistor TF1 to the transistor TF2 is, for example, 1:K. A base and a collector of the bipolar transistor TF4 are coupled to the node NF2, and a base of the bipolar transistor TF5 is coupled to the node NF2. When base-emitter voltages of the npn bipolar transistors TF4 and TF5 are defined as VBE1 and VBE2, respectively, by determining the constant of the circuit element such that ΔVBE=VBE1−VBE2 has a positive temperature characteristic, the current source 56 of FIG. 17 can be used as a current source of PTAT.

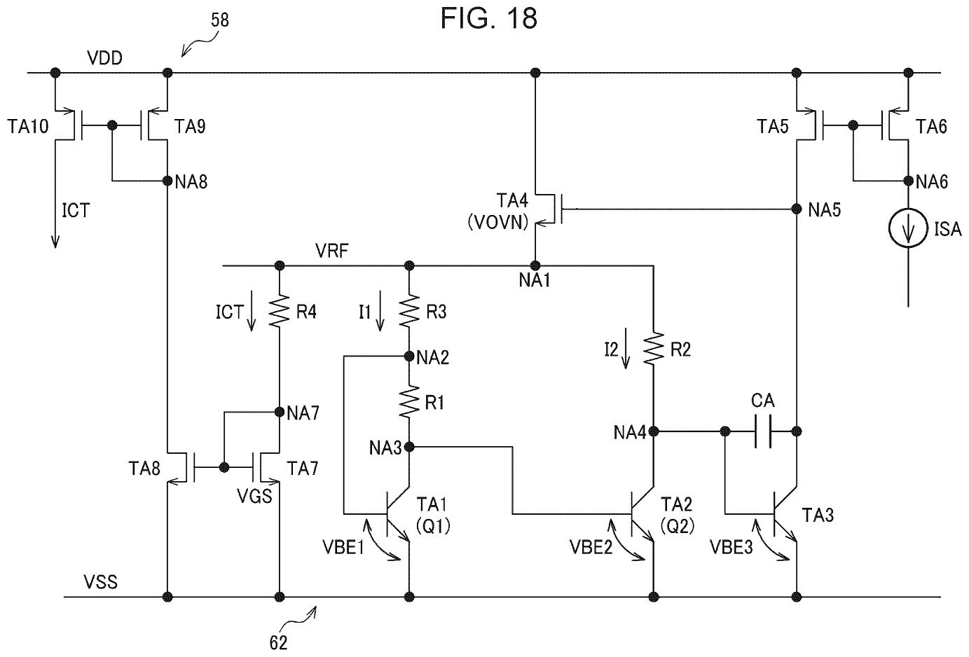

FIG. 18 shows a configuration example of a current source 58 of CTAT. In FIG. 18, P-type transistors TA9 and TA10 that constitute the current mirror circuit, N-type transistors TA7 and TA8 that constitute the current mirror circuit, and a resistor R4 are provided. When a gate-source voltage of the diode-connected transistor TA7 is defined as VGS, the current flowing through the resistor R4 is represented by ICT=(VRF-VGS)/R4. By determining the circuit constant such that the VRF-VGS has a negative temperature characteristic, it is possible to realize the current source 58 of CTAT that causes the current ICT to flow.

As described above, as shown in FIGS. 1 and 2, the circuit device 20 of the present embodiment includes the oscillation circuit 30 that causes the resonator 10 to oscillate and generates the oscillation signal, and the temperature compensation circuit 40 that outputs the temperature compensation voltage VCP of the oscillation frequency of the oscillation signal to the oscillation circuit 30 based on the temperature detection voltage VTS from the temperature detection circuit 50. In addition, the circuit device 20 includes the power supply circuit 90 that generates the power supply voltage VDL of the temperature compensation circuit 40, and the reference voltage generation circuit 60 for temperature compensation that generates the reference voltage VRC for temperature compensation and outputs the reference voltage VRC to the temperature compensation circuit 40. As described in FIG. 12, the noise (A1) of the reference voltage VRC is smaller than the noise (A2, A3) of the power supply voltage VDL. On the other hand, as described in FIG. 13, the temperature characteristics (B2 and B3) of the power supply voltage VDL are flatter than the temperature characteristic (B1) of the reference voltage VRC.

Thus, as the reference voltage VRC becomes low noise, the temperature compensation voltage VCP generated based on the reference voltage VRC also becomes low noise. Therefore, it is possible to realize low noise of the oscillation signal generated based on the temperature compensation voltage VCP or the clock signal based on the oscillation signal. In addition, the temperature characteristics of the power supply voltage VDL for temperature compensation become flat, so that it is possible to realize stable operation of the temperature compensation circuit 40 and to prevent a situation in which the voltage range of the temperature compensation voltage VCP decreases.

In addition, in the present embodiment, a slope of a first-order temperature characteristic of the power supply voltage VDL is smaller than a slope of a first-order temperature characteristic of the reference voltage VRC. For example, the slope of the first-order temperature characteristic of the voltage VRG shown in B2 and B3 of FIG. 13 corresponding to the power supply voltage VDL is smaller than the slope of the first-order temperature characteristic of the voltage VRG shown in B1 of FIG. 13 used to generate the reference voltage VRC. Therefore, the slope of the first-order temperature characteristic of the power supply voltage VDL is smaller than the slope of the first-order temperature characteristic of the reference voltage VRC. As described above, the slope of the first-order temperature characteristic of the power supply voltage VDL is small, so that the fluctuation of the power supply voltage VDL in the usage temperature range decreases, and it is possible to realize the stable operation of the temperature compensation circuit 40 and to prevent the voltage range of the temperature compensation voltage VCP from decreasing.

In addition, as shown in FIG. 3, the temperature compensation circuit 40 includes the current generation circuit 42 and the current-voltage conversion circuit 46. The current generation circuit 42 generates a temperature compensation current ICP based on the temperature detection voltage VTS. The current-voltage conversion circuit 46 includes the operational amplifier OPD1 that operates based on the power supply voltage VDL for temperature compensation, and generates a temperature compensation voltage VCP by converting the temperature compensation current ICP into a voltage using the operational amplifier OPD1. The reference voltage VRC is input to, for example, the non-inverting input terminal, which is the first input terminal of the operational amplifier OPD1.

In this way, the operational amplifier OPD1 of the current-voltage conversion circuit 46 can stably operate based on the power supply voltage VDL having a flat temperature characteristic, and it is possible to prevent the voltage range of the temperature compensation voltage VCP from decreasing. In addition, since the reference voltage VRC having low noise is input to the first input terminal of the operational amplifier OPD1, the current-voltage conversion circuit 46 can generate a temperature compensation voltage VCP having low noise.

In addition, as shown in FIG. 3, the current-voltage conversion circuit 46 includes a feedback resistor RD provided between the output terminal and, for example, an inverting input terminal which is the second input terminal of the operational amplifier OPD1. The temperature compensation current ICP is input to the second input terminal of the operational amplifier OPD1.

In this way, the current-voltage conversion circuit 46 can convert the temperature compensation current ICP into the temperature compensation voltage VCP by using the operational amplifier OPD1 and the resistor RD. Since the operational amplifier OPD1 generates the temperature compensation voltage VCP based on the reference voltage VRC input to the first input terminal, it is possible to realize low noise of the temperature compensation voltage VCP.

As shown in FIGS. 6, 9, and 11, the reference voltage generation circuit 60 includes the reference circuit 62 that generates a BGR voltage (bandgap reference voltage) as a voltage VRF, and generates a reference voltage VRC based on the voltage VRF generated by the reference circuit 62.

In this way, the BGR voltage having low noise is generated by the reference circuit 62, and the reference voltage VRC is generated based on the BGR voltage having low noise. Therefore, it is possible to realize low noise of the reference voltage VRC.

As shown in FIGS. 9 and 11, the reference voltage generation circuit 60 includes the regulator 66, and generates a reference voltage VRC based on a voltage generated based on the voltage VRF, which is the BGR voltage, by the regulator 66.

By providing such the regulator 66, even when an output impedance of the reference circuit 62 is high, it becomes possible to generate the reference voltage VRC based on the voltage that the regulator 66 generates using the voltage VRF.

In addition, as shown in FIG. 16, the regulator 66 of the reference voltage generation circuit 60 includes the operational amplifier OPE, the depletion N-type transistor TE, and the voltage division circuit 67. The operational amplifier OPE receives, at the first input terminal such as a non-inverting input terminal, the voltage VRF that is the BGR voltage, and receives, at the second input terminal such as the inverting input terminal, the feedback voltage VFB. The depletion N-type transistor TE is provided between the node of VDD, which is the first power supply node, and the output node NE1 of the voltage VRG that is the regulated voltage, and the output of the operational amplifier OPE is input to the gate. As described above, the transistor TE may be the P-type transistor. In addition, the voltage division circuit 67 is provided between the output node NE1 of the voltage VRG and the node of VSS, which is the second power supply node, and outputs a voltage obtained by dividing the voltage VRG as the feedback voltage VFB. As shown in FIGS. 5 and 11, the voltage VRG generated by the regulator 66 of the reference voltage generation circuit 60 is used as, for example, the reference power supply voltage VD of the voltage generation circuit 68.

In this way, the regulator 66 can regulate the power supply voltage VDD of the first power supply node based on the voltage VRF that is the BGR voltage and generate a voltage VRG which is the regulated voltage. The reference voltage generation circuit 60 can generate a reference voltage VRC by using the voltage VRG.

In addition, the reference voltage VRC has a temperature characteristic of a first polarity in the usage temperature range. The first polarity is one of a positive polarity and a negative polarity. For example, in B1 of FIG. 13, a temperature characteristic of the voltage VRG for generating the reference voltage VRC has a negative polarity, and in this case, a temperature characteristic of the reference voltage VRC has a negative polarity.

Thus, even when the reference voltage VRC has the temperature characteristic of the first polarity instead of the flat temperature characteristic, it becomes possible to cancel the temperature characteristic of the first polarity of the reference voltage VRC by first-order correction or the like in the temperature compensation circuit 40, as described later. For example, the temperature characteristic of the first polarity of the reference voltage VRC can be canceled by the first-order correction (first-order compensation) in the first-order correction circuit 43 of FIG. 3.

In addition, as shown in FIGS. 10 and 11, the power supply circuit 90 includes the reference circuit 92 that generates a voltage VRF which is a reference voltage for power supply, and generates a power supply voltage VDD based on the voltage VRF. The reference circuit 92 generates, as a voltage VRF that is a reference voltage for power supply, a voltage obtained by adding a first voltage, which is generated by causing a first current having a temperature characteristic of a first polarity to flow through a first resistor, to a second voltage. Taking FIGS. 14 and 15 as examples, the first current having the temperature characteristic of the first polarity is, for example, a current IPT of PTAT having a positive temperature characteristic. The first resistor is the resistor RC1 of FIG. 14 or the resistor RH1 of FIG. 15. The first voltage is a voltage that is generated by causing the current IPT to flow through the resistor RC1 or the resistor RH1. In addition, the second voltage is the voltage VGS between the gate and the source of the transistor TC2 in which the gate and the drain are coupled to each other in FIG. 14. In addition, in FIG. 15, the second voltage is a voltage generated by causing the current IPT, which is the first current, and the current ICT, which is the second current having the temperature characteristic of the second polarity different from the first polarity, to flow through the resistor RH3, which is a third resistor. Here, the current IPT, which is the first current, has a positive temperature characteristic, and the current ICT, which is the second current, has a negative temperature characteristic. However, the positive and negative polarities may be reversed.

In this way, it becomes possible to generate, as a voltage VRF, a voltage obtained by adding the first voltage, which is generated by causing the current IPT to flow through the resistor RC1 or the resistor RH1, with either the voltage VGS between the gate and the source of the transistor TC2, or the second voltage, which is the voltage generated by causing the current IPT and the current ICT to flow through the resistor RH3. Accordingly, the voltage VRF, which is a power supply reference voltage having a flat temperature characteristic overthe usage temperature range, and the power supply voltage VDL having a flat temperature characteristic can be generated based on the voltage VRF.

In addition, as shown in FIGS. 10 and 11, the power supply circuit 90 includes the regulator 96, and the regulator 96 generates a power supply voltage VDL based on the voltage VRF which is the reference voltage for power supply. For example, the regulator 96 regulates the power supply voltage VDD based on the voltage VRF, generates a power supply voltage VDL, and supplies the power supply voltage VDL to the temperature compensation circuit 40.

By providing such a regulator 96, even when an output impedance of the reference circuit 92 is high, the regulator 96 having a low output impedance can generate and supply a power supply voltage VDL based on the voltage VRF.

In addition, as shown in FIG. 16, the regulator 96 of the power supply circuit 90 includes the operational amplifier OPE, the depletion N-type transistor TE, and the voltage division circuit 97. The operational amplifier OPE receives, at the first input terminal such as a non-inverting input terminal, the voltage VRF that is the reference voltage for power supply, and receives, at the second input terminal such as the inverting input terminal, the feedback voltage VFB. The depletion N-type transistor TE is provided between the node of VDD, which is the first power supply node, and the output node NE1 of the voltage VRG that is the regulated voltage, and the output of the operational amplifier OPE is input to the gate. As described above, the transistor TE may be the P-type transistor. In addition, the voltage division circuit 97 is provided between the output node NE1 of the voltage VRG and the node of VSS, which is the second power supply node, and outputs a voltage obtained by dividing the voltage VRG as the feedback voltage VFB. As shown in FIG. 11, the voltage VRG generated by the regulator 96 of the power supply circuit 90 is supplied to the temperature compensation circuit 40 as the power supply voltage VDL.

In this way, the regulator 96 can regulate the power supply voltage VDD of the first power supply node based on the voltage VRF that is the reference voltage for power supply and generate a voltage VRG which is the regulated voltage. The power supply circuit 90 is configured to supply the voltage VRG to the temperature compensation circuit 40 as the power supply voltage VDL.

In addition, in FIG. 14, the reference circuit 92 includes the transistor TC1, the resistor RC1, and the transistor TC2. The transistor TC1 is a first current source, and the resistor RC1 is the first resistor.

The transistor TC1, which is the first current source, is provided between the node of VDD and the node NC1, and causes the current IPT having the temperature characteristic of the first polarity to flow. The node of VDD is a first power supply node, and the node NC1 is a first node. In addition, the current IPT is a first current, and the temperature characteristic of the first polarity is, for example, a positive temperature characteristic.

The resistor RC1, which is the first resistor, is provided between the node of VDD and the node NC1 in series with the transistor TC1, which is the first current source. The transistor TC2 is provided between the node NC1 and the node of VSS, and a gate and a drain are coupled to the node NC1. The node of VSS is a second power supply node. Thus, the voltage VRF, which is the reference voltage for power supply, is output from the output node NCQ between the transistor TC1 and the resistor RC1.

According to the reference circuit 92 having such a configuration, when a gate-source voltage of the transistor TC2 is defined as VGS and the resistance value of the resistor RC1 is represented by RC1 having the same reference signs, the voltage of VRF=VGS+RC1. IPT is output from the output node NCQ. Therefore, for example, by adjusting the resistance value of the resistor RC1, it is possible to generate the voltage VRF having a flat temperature characteristic with the temperature characteristic of the first polarity of the current IPT and the temperature characteristic of the second polarity of the voltage VGS.

In addition, in FIG. 15, the reference circuit 92 includes the transistor TH1, the resistor RH1, the transistor TH2, the resistor RH2, and the resistor RH3. The transistor TH1 is the first current source, the resistor RH1 is the first resistor, the transistor TH2 is a second current source, the resistor RH2 is a second resistor, and the resistor RH3 is a third resistor.

The transistor TH1, which is the first current source, is provided between the node of VDD and the node NH1, and causes the current IPT having the temperature characteristic of the first polarity to flow. The temperature characteristic of the first polarity is, for example, the positive temperature characteristic. The node NH1 is a first node. In addition, the current IPT is a first current. In addition, the resistor RH1, which is the first resistor, is provided between the node of VDD and the node NH1 in series with the transistor TH1, which is the first current source.

The transistor TH2, which is the second current source, is provided between the node of VDD and the node NH1, and causes the current ICT having the temperature characteristic of the second polarity different from the first polarity to flow. The temperature characteristic of the second polarity is, for example, the negative temperature characteristic. In addition, the current ICT is a second current. In addition, the resistor RH2, which is the second resistor, is provided between the node of VDD and the node NH1 in series with the transistor TH2, which is the second current source.

In addition, the resistor RH3 is provided between the node NH1 and the node of VSS, and the current IPT and the current ICT flow through the resistor RH3. Thus, the voltage VRF, which is the reference voltage for power supply, is output from the output node NHQ between the transistor TH1 and the resistor RH1.

In the reference circuit 92 having such a configuration, when resistance values of the resistors RH1, RH2, and RH3 are represented by the same reference signs RH1, RH2, and RH3, the voltage VRF of VRF=RH1·IPT+RH3·(IPT+ICT) is output from the output node NHQ between the transistor TH1 and the resistor RH1. Since the current IPT has the temperature characteristic of the first polarity and the current ICT has the temperature characteristic of the second polarity different from the first polarity, the voltage VRF having a flat temperature characteristic can be generated by adjusting the resistance value of the resistor RH1.

### 3. First-Order Correction

In the present embodiment, since the reference voltage VRC has a first-order temperature characteristic as described in B1 of FIG. 13, there is a possibility that an appropriate temperature compensation voltage VCP cannot be generated. However, as shown in FIG. 3, since the first-order correction circuit 43 of the temperature compensation circuit 40 performs the first-order correction of temperature compensation, it is possible to perform the correction of canceling the first-order temperature characteristics of the reference voltage VRC by using the first-order correction. This point will be described.

For example, in FIG. 3, when the output voltage of the operational amplifier OPD2 is defined as VC1 and the higher-order current from the higher-order correction circuit 44 is defined as ICU, the temperature compensation voltage VCP can be represented as in the following Equation (4).

$$V C P = - \frac{R D}{R D 3} V C 1 - I C U \cdot R D + ( 1 + \frac{R D}{R D 3} ) V R C \qquad ( 4 )$$

When the voltage VC1 and the reference voltage VRC are represented by first-order equations with respect to a temperature (t), they are represented as in the following Equation (5).

$$V C 1 = at + b \qquad ( 5 )$$

$$V R C = ct + d$$

Then, by substituting the above Equation (5) into the above Equation (4), a temperature compensation voltage VCP can be represented as the following Equation (6).

$$\begin{matrix}V C P = - \frac{R D}{R D 3} ( at + b ) - I C U \cdot R D + ( 1 + \frac{R D}{R D 3} ) ( ct + d ) \\ = \begin{matrix}( - \frac{R D}{R D 3} a + ( 1 + \frac{R D}{R D 3} ) c ) t + ( - \frac{R D}{R D 3} b + ( 1 + \frac{R D}{R D 3} ) d ) - \\ I C U \cdot R D\end{matrix}\end{matrix} \qquad ( 6 )$$

Therefore, even when c in the above Equation (5) is not 0 and the reference voltage VRC has the first-order temperature characteristic represented by ct+d, it can be understood from the above Equation (6) that, in the first-order correction circuit 43, the temperature compensation voltage VCP can be adjusted by first-order gain adjustment for correcting the resistance value of the resistor RD3. Therefore, even when the reference voltage VRC has a first-order temperature characteristic, it is possible to perform correction that cancels the first-order temperature characteristic of the reference voltage VRC by using the first-order correction circuit 43 of the temperature compensation circuit 40.

As described above, the circuit device of the present embodiment includes an oscillation circuit configured to cause a resonator to oscillate and generate an oscillation signal, a temperature compensation circuit configured to output a temperature compensation voltage for an oscillation frequency of the oscillation signal to the oscillation circuit based on a temperature detection voltage from a temperature detection circuit, a power supply circuit configured to generate a power supply voltage of the temperature compensation circuit, and a reference voltage generation circuit for temperature compensation configured to generate a reference voltage for temperature compensation and output the reference voltage to the temperature compensation circuit. Noise of the reference voltage is smaller than noise of the power supply voltage, and a temperature characteristic of the power supply voltage is flatter than a temperature characteristic of the reference voltage.

According to the present embodiment, since the reference voltage has low noise, the temperature compensation voltage generated based on the reference voltage also has low noise, and low noise of the oscillation signal generated based on the temperature compensation voltage can be realized. Further, the temperature characteristic of the power supply voltage for temperature compensation becomes flat, so that it is possible to realize stable operation of the temperature compensation circuit and the like.

In addition, in the present embodiment, a slope of a first-order temperature characteristic of the power supply voltage may be smaller than a slope of a first-order temperature characteristic of the reference voltage.

In this way, the fluctuation of the power supply voltage for temperature compensation in the usage temperature range decreases, and the stable operation of the temperature compensation circuit can be realized.

In addition, in the present embodiment, the temperature compensation circuit may include a current generation circuit that generates a temperature compensation current based on a temperature detection voltage, and a current-voltage conversion circuit that includes an operational amplifier that operates based on a power supply voltage for temperature compensation, and that generates a temperature compensation voltage by converting the temperature compensation current into a voltage using the operational amplifier. The reference voltage may be input to a first input terminal of the operational amplifier.

In this way, it is possible for the operational amplifier of the current-voltage conversion circuit to stably operate based on the power supply voltage having a flat temperature characteristic. In addition, since the reference voltage having low noise is input to the first input terminal of the operational amplifier, the temperature compensation voltage having low noise can be generated.

In addition, in the present embodiment, the current-voltage conversion circuit may include a feedback resistor provided between an output terminal and a second input terminal of the operational amplifier, and the temperature compensation current may be input to the second input terminal of the operational amplifier.

In this way, the temperature compensation current can be converted into the temperature compensation voltage by using the operational amplifier and the feedback resistor, and the temperature compensation voltage is generated based on the reference voltage input to the first input terminal of the operational amplifier. Therefore, it is possible to realize the low noise of the temperature compensation voltage.

In addition, in the present embodiment, the reference voltage generation circuit may include a reference circuit that generates a bandgap reference voltage, and generate the reference voltage based on the bandgap reference voltage generated by the reference circuit.

In this way, since the reference voltage is generated based on the bandgap reference voltage having low noise, it is possible to realize low noise of the reference voltage.

In addition, in the present embodiment, the reference voltage generation circuit may include a regulator, and may generate the reference voltage based on a voltage generated by the regulator based on the bandgap reference voltage.

In this way, even when an output impedance of the reference circuit is high, the reference voltage can be generated based on the voltage generated by the regulator having a low output impedance.

In addition, in the present embodiment, the regulator may include an operational amplifier in which a bandgap reference voltage is input to the first input terminal and the feedback voltage is input to the second input terminal, and a depletion N-type transistor or a P-type transistor that is provided between the first power supply node and an output node of a regulated voltage and that has a gate receiving output of the operational amplifier. In addition, the regulator may include a voltage division circuit provided between the output node of the regulated voltage and the second power supply node and outputting a voltage obtained by dividing the regulated voltage as a feedback voltage.

In this way, the power supply voltage of the first power supply node is regulated based on the bandgap reference voltage, so that the regulated voltage is generated and the reference voltage can be generated by using the regulated voltage.

In addition, in the present embodiment, the reference voltage may have a temperature characteristic of a first polarity in the usage temperature range.

In this way, even when the reference voltage has the temperature characteristic of the first polarity, it is possible to cancel the temperature characteristic of the first polarity of the reference voltage by performing the first-order correction in the temperature compensation circuit or the like.

In addition, in the present embodiment, the power supply circuit may include a reference circuit that generates a reference voltage for power supply, and generate a power supply voltage based on the reference voltage for power supply. The reference circuit may generate, as a reference voltage for power supply, a voltage obtained by adding a first voltage, which is generated by causing a first current having a temperature characteristic of a first polarity to flow through a first resistor, and a second voltage. The second voltage may be a gate-source voltage of a transistor in which a gate and a drain are coupled to each other, or a voltage generated by causing the first current and a second current having a temperature characteristic of a second polarity different from the first polarity to flow through a third resistor.

In this way, the first voltage is generated by causing the first current having the temperature characteristic of the first polarity to flow through the first resistor. The voltage between the gate and the source of the transistor in which the gate and the drain are coupled to each other, or the voltage generated by causing the first current and the second current having the temperature characteristic of the second polarity to flow through the third resistor, is generated as the second voltage. The voltage obtained by adding the first voltage and the second voltage can be generated as the reference voltage for power supply.

In addition, in the present embodiment, the power supply circuit may include a regulator, and the regulator may generate a power supply voltage based on the reference voltage for power supply.

In this way, even when an output impedance of the reference circuit is high, the power supply voltage can be generated based on the reference voltage for power supply by the regulator having a low output impedance.

In addition, in the present embodiment, the regulator may include an operational amplifier in which the reference voltage for power supply is input to the first input terminal and the feedback voltage is input to the second input terminal, and a depletion N-type transistor or a P-type transistor that is provided between the first power supply node and an output node of a regulated voltage and that has a gate receiving output of the operational amplifier. In addition, the regulator may include a voltage division circuit provided between the output node of the regulated voltage and the second power supply node and outputting a voltage obtained by dividing the regulated voltage as a feedback voltage.

In this way, the power supply voltage of the first power supply node is regulated based on the reference voltage for power supply, so that the regulated voltage is generated and the regulated voltage can be supplied to the temperature compensation circuit as the power supply voltage.

In addition, in the present embodiment, the power supply circuit may include a reference circuit that generates a reference voltage for power supply, and generate a power supply voltage based on the reference voltage for power supply. In addition, the reference circuit may include a first current source that is provided between the first power supply node and the first node and causes the first current having the temperature characteristic of the first polarity to flow, and the first resistor that is provided between the first power supply node and the first node in series with the first current source. In addition, the reference circuit may include a transistor that is provided between the first node and the second power supply node and has a gate and a drain coupled to the first node. The reference voltage for power supply may be output from an output node between the first current source and the first resistor.

In this way, the reference voltage for power supply having a flat temperature characteristic can be generated by the temperature characteristic of the first polarity of the first current and the temperature characteristic of the second polarity of the gate-source voltage of the transistor in which the gate and the drain are coupled to each other.

In addition, in the present embodiment, the power supply circuit may include a reference circuit that generates a reference voltage for power supply, and generate a power supply voltage based on the reference voltage for power supply. In addition, the reference circuit may include a first current source that is provided between the first power supply node and the first node and causes the first current having the temperature characteristic of the first polarity to flow, and the first resistor that is provided between the first power supply node and the first node in series with the first current source. In addition, the reference circuit may include a second current source that is provided between the first power supply node and the first node and causes a second current having a temperature characteristic of a second polarity different from the first polarity to flow, and a second resistor that is provided between the first power supply node and the first node in series with the second current source. In addition, the reference circuit may include a third resistor provided between the first node and the second power supply node and through which the first current and the second current flow. The reference voltage for power supply may be output from an output node between the first current source and the first resistor.

In this way, the first current of the temperature characteristic of the first polarity flows to the first resistor, and the first current of the temperature characteristic of the first polarity and the second current of the temperature characteristic of the second polarity flow through the third resistor. Therefore, the reference voltage for power supply having a flat temperature characteristic can be output from the output node.

In addition, the oscillator of the present embodiment includes the circuit device and the resonator described above.

Although the present embodiment is described in detail as described above, those skilled in the art can easily understand that many modifications that do not substantially deviate from new matters and effects of the present disclosure are possible. Therefore, all such modification examples fall within the scope of the present disclosure. For example, a term described at least once together with a different term having a broader meaning or the same meaning in the specification or the drawings can be replaced with a different term anywhere in the specification or drawings. In addition, all combinations of the present embodiment and modification examples also fall within the scope of the present disclosure. In addition, the configuration, operation, and the like of the circuit device and the oscillator are not limited to those described in the present embodiment, and various modifications can be made.

What is claimed is:

1. A circuit device comprising:
an oscillation circuit configured to cause a resonator to oscillate and generate an oscillation signal;
a temperature compensation circuit configured to output a temperature compensation voltage for an oscillation frequency of the oscillation signal to the oscillation circuit based on a temperature detection voltage from a temperature detection circuit;
a power supply circuit configured to generate a power supply voltage of the temperature compensation circuit; and
a reference voltage generation circuit for temperature compensation configured to generate a reference voltage for temperature compensation and output the reference voltage to the temperature compensation circuit, wherein
noise of the reference voltage is smaller than noise of the power supply voltage, and
a temperature characteristic of the power supply voltage is flatter than a temperature characteristic of the reference voltage.

2. The circuit device according to claim 1, wherein
a slope of a first-order temperature characteristic of the power supply voltage is smaller than a slope of a first-order temperature characteristic of the reference voltage.

3. The circuit device according to claim 1, wherein
the temperature compensation circuit includes
a current generation circuit configured to generate a temperature compensation current based on the temperature detection voltage, and
a current-voltage conversion circuit including an operational amplifier that operates based on the power supply voltage for temperature compensation, and configured to generate the temperature compensation voltage by converting the temperature compensation current into a voltage using the operational amplifier, and
the reference voltage is input to a first input terminal of the operational amplifier.

4. The circuit device according to claim 3, wherein
the current-voltage conversion circuit includes
a feedback resistor provided between an output terminal and a second input terminal of the operational amplifier, and
the temperature compensation current is input to the second input terminal of the operational amplifier.

5. The circuit device according to claim 1, wherein
the reference voltage generation circuit includes a reference circuit that is configured to generate a bandgap reference voltage, and generates the reference voltage based on the bandgap reference voltage generated by the reference circuit.

6. The circuit device according to claim 5, wherein
the reference voltage generation circuit includes a regulator, and generates the reference voltage based on a voltage generated by the regulator based on the bandgap reference voltage.

7. The circuit device according to claim 6, wherein
the regulator includes
an operational amplifier in which the bandgap reference voltage is input to a first input terminal and a feedback voltage is input to a second input terminal,
a depletion N-type transistor or a P-type transistor that is provided between a first power supply node and an output node of a regulated voltage, and has a gate receiving output of the operational amplifier, and
a voltage division circuit that is provided between the output node of the regulated voltage and a second power supply node, and configured to output a voltage obtained by dividing the regulated voltage as the feedback voltage.

8. The circuit device according to claim 5, wherein
the reference voltage has a temperature characteristic of a first polarity in a usage temperature range.

9. The circuit device according to claim 1, wherein
the power supply circuit includes a reference circuit that is configured to generate a reference voltage for power supply, and generates the power supply voltage based on the reference voltage for power supply,
the reference circuit generates a voltage obtained by adding a first voltage generated by causing a first current having a temperature characteristic of a first polarity to flow through a first resistor and a second voltage, as the reference voltage for power supply, and
the second voltage is a gate-source voltage of a transistor in which a gate and a drain are coupled to each other, or a voltage generated by causing the first current and a second current having a temperature characteristic of a second polarity different from the first polarity to flow through a third resistor.

10. The circuit device according to claim 9, wherein
the power supply circuit includes a regulator, and the regulator generates the power supply voltage based on the reference voltage for power supply.

11. The circuit device according to claim 10, wherein
the regulator includes
an operational amplifier in which the reference voltage for power supply is input to a first input terminal and a feedback voltage is input to a second input terminal,
a depletion N-type transistor or a P-type transistor that is provided between a first power supply node and an output node of a regulated voltage, and has a gate receiving output of the operational amplifier, and
a voltage division circuit that is provided between the output node of the regulated voltage and a second power supply node, and configured to output a voltage obtained by dividing the regulated voltage as the feedback voltage.

12. The circuit device according to claim 1, wherein
the power supply circuit includes a reference circuit that is configured to generate a reference voltage for power supply, and generates the power supply voltage based on the reference voltage for power supply,
the reference circuit includes
a first current source that is provided between a first power supply node and a first node and causes a first current having a temperature characteristic of a first polarity to flow,
a first resistor that is provided between the first power supply node and the first node in series with the first current source, and
a transistor that is provided between the first node and a second power supply node and has a gate and a drain coupled to the first node, and
the reference voltage for power supply is output from an output node between the first current source and the first resistor.

13. The circuit device according to claim 1, wherein
the power supply circuit includes a reference circuit that is configured to generate a reference voltage for power supply, and generates the power supply voltage based on the reference voltage for power supply,
the reference circuit includes
a first current source that is provided between a first power supply node and a first node and causes a first current having a temperature characteristic of a first polarity to flow,
a first resistor that is provided between the first power supply node and the first node in series with the first current source,
a second current source that is provided between the first power supply node and the first node and causes a second current having a temperature characteristic of a second polarity different from the first polarity to flow,
a second resistor that is provided between the first power supply node and the first node in series with the second current source, and
a third resistor that is provided between the first node and a second power supply node and causes the first current and the second current to flow, and
the reference voltage for power supply is output from an output node between the first current source and the first resistor.

14. An oscillator comprising:
the circuit device according to claim 1; and
the resonator.
